(19) United States
(12) Patent Application Publication
(10) Pub. No.: US 2026/0068644 A1
(43) Pub. Date: Mar. 5, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Ching-Han MAO, Hsinchu City (TW); Chih-Yi CHANG, New Taipei City (TW); Jau-Jiun HUANG, Kaohsiung City (TW); Chien-Hsueh SHIH, Hsinchu (TW); Chun-Chieh LIN, Taichung City (TW)

(21) Appl. No.: 19/012,214

(22) Filed: Jan. 7, 2025

Related U.S. Application Data
(60) Provisional application No. 63/690,556, filed on Sep. 4, 2024.

(51) Int. Cl. H01L 23/528; H01L 21/768; H01L 23/532

(52) U.S. Cl. CPC H01L 23/5283

(57) ABSTRACT

A layer of conductive material is formed above a bottom-most layer of interconnect structures in an interconnect layer of a semiconductor device, and the layer of conductive material is etched to define the bottom-most layer of metallization structures from the layer of conductive material. To reduce the likelihood of collapse of the free-standing metallization structures, the exposed sidewall surfaces of the free-standing metallization structures may be oxidized to form metal-oxide sidewalls for the free-standing metallization structures. The metal-oxide sidewalls may be formed using a self-aligned oxidation technique that specifically targets the sidewalls of the free-standing metallization structures for oxidation. The metal-oxide sidewalls may be formed of a metal-oxide material that increases the mechanical strength of the free-standing metallization structures, which enables the free-standing metallization structures to resist collapsing.

### CROSS-REFERENCE TO RELATED APPLICATION

This patent application claims priority to U.S. Provisional Patent Application No. 63/690,556, filed on Sep. 4, 2024, and entitled “SEMICONDUCTOR DEVICE AND METHODS OF FORMATION.” The disclosure of the prior Application is considered part of and is incorporated by reference into this patent application.

### BACKGROUND

An interconnect layer (sometimes referred to as a back end region or a back end of line (BEOL) region) is a region of a semiconductor device that includes a plurality of layers of conductive structures that are arranged to carry signals and/or to provide power distribution throughout the semiconductor device. The plurality of layers of conductive structures may include various vertically-arranged layers of interconnect structures (e.g., vias) and layers of metallization structures (e.g., trenches, conductive lines, traces).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIGS. 2A-2C are diagrams of an example implementation of forming a portion of a semiconductor device described herein.

FIGS. 3A-3M are diagrams of an example implementation of forming a portion of a semiconductor device described herein.

FIG. 4 is a flowchart of an example process associated with forming a semiconductor device described herein.

FIG. 5 is a flowchart of an example process associated with forming a semiconductor device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An interconnect layer of a semiconductor device may be formed above a device layer of the semiconductor device. The device layer may include a substrate layer of the semiconductor device and integrated circuit devices (e.g., transistors, capacitors, diodes, memory cells) in and/or on the semiconductor substrate. A layer of contact structures (e.g., source/drain contacts, gate contacts) may be included in the device layer, and a bottom-most layer of interconnect structures (e.g., source/drain interconnect structures, gate interconnect structures, sometimes referred to as a via-0 or V0 layer) may be located at the bottom of the interconnect layer between the contact structures and higher layers in the interconnect layer. The contact structures and the bottom-most layer of interconnect structures may electrically connect the integrated circuit devices and the higher layers of conductive structures in the interconnect layer.

A bottom-most layer of metallization structures (sometimes referred to as a metal-0 or M0 layer) in the interconnect layer may be included above the bottom-most layer of interconnect structures. The bottom-most layer of metallization structures may be formed by forming recesses in a dielectric layer above the bottom-most layer of interconnect structures such that the top surfaces of the bottom-most layer of interconnect structures are exposed through the recesses, and depositing the material of the bottom-most layer of metallization structures in the recesses such that the bottom-most layer of metallization structures are electrically coupled to the bottom-most layer of interconnect structures.

However, as the size of integrated circuit devices is reduced, the size and spacing between metallization structures in the interconnect layer is also reduced. Thus, the size and spacing between metallization structures in the bottom-most layer of metallization structures is reduced, which may result in reduced gap-filing performance for the bottom-most layer of metallization structures. This may result in the occurrence of voids and/or other discontinuities in the bottom-most layer of metallization structures, which may increase the contact resistance of the bottom-most layer of metallization structures and/or may result in electrical disconnects between the bottom-most layer of metallization structures and the bottom-most layer of interconnect structures. The gap-filling performance may be worsened by the inclusion of liners in the recesses that protect against material migration from the bottom-most layer of metallization structures and/or provide for enhanced adhesion between the bottom-most layer of metallization structures and the dielectric layer.

In some implementations described herein, a layer of conductive material is formed above a bottom-most layer of interconnect structures in an interconnect layer of a semiconductor device, and the layer of conductive material is etched to define the bottom-most layer of metallization structures from the layer of conductive material, as opposed to forming the bottom-most layer of metallization structures in recesses in a dielectric layer. The areas between the free-standing metallization structures may then be sealed with a low dielectric constant (low-k) dielectric plug so that airgaps remain between the metallization structures as low-k electrical isolation. The airgaps enable the bottom-most layer of metallization structures to be electrically isolated without the use of liners, which provides for a greater area for the bottom-most layer of metallization structures and a lower contact resistance.

To reduce the likelihood of collapse of the free-standing metallization structures, the exposed sidewall surfaces of the free-standing metallization structures may be oxidized to form metal-oxide sidewalls for the free-standing metallization structures. The metal-oxide sidewalls may be formed using a self-aligned oxidation technique that specifically targets the sidewalls of the free-standing metallization structures for oxidation. The metal-oxide sidewalls may be formed of a metal-oxide material that increases the mechanical strength of the free-standing metallization structures (which enables the free-standing metallization structures to resist collapsing) and that has a low electrical resistance (which has minimal impact on the resistance of the free-standing metallization structures). In this way, the low electrical resistance achieved for the bottom-most layer of metallization structures, alone or in combination with the low-k electrical isolation provided by the airgaps, enables a low resistance-capacitance time constant (RC time constant) to be achieved for the bottom-most layer of metallization structures. The low RC time constant enables faster signal propagation speeds to be achieved through the bottom-most layer of metallization structures and/or enables faster switching speeds to be achieved for the integrated circuit devices of the semiconductor device, among other examples.

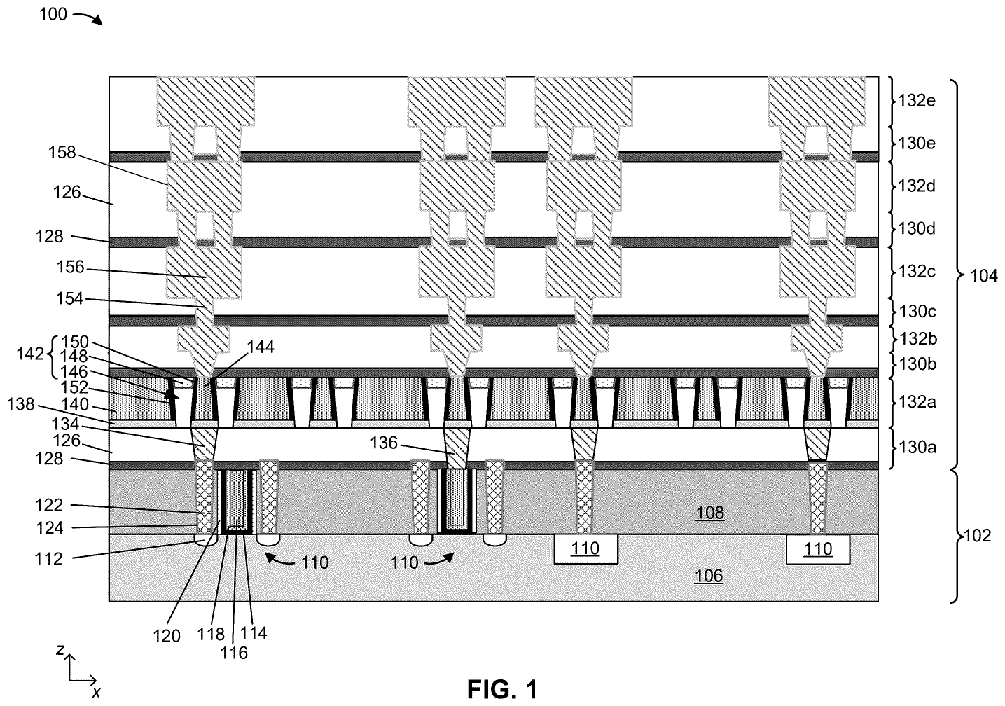

FIG. 1 is a diagram of an example semiconductor device 100 described herein. The semiconductor device 100 may include system on chip (SoC) device, a logic device such as a central processing unit (CPU) or a graphics processing unit (GPU), a memory device (e.g., a high bandwidth memory (HBM) device), an image sensor device (e.g., a complementary metal-oxide-semiconductor (CMOS) image sensor device), a display device (e.g., an organic light emitting diode (OLED) display device), and/or another type of semiconductor device.

As shown in FIG. 1, the semiconductor device 100 may include a device layer 102 and an interconnect layer 104 arranged in a z-direction in the semiconductor device 100 above the device layer 102. For example, the interconnect layer 104 may be located above the device layer 102. As another example, the interconnect layer 104 may be located below the device layer 102.

The device layer 102 may also be referred to as a front end region or front end of line (FEOL) region of the semiconductor device 100. The interconnect layer 104 may also be referred to a back end region or back end of line (BEOL) region of the semiconductor device 100, and may include conductive structures that are arranged to carry signals and/or provide power distribution throughout the semiconductor device 100. In some implementations, the semiconductor device 100 includes interconnect layers 104 above and below the device layer 102. A first interconnect layer 104 on a first side of the device layer 102 may be used for signal propagation throughout the semiconductor device 100, and a second interconnect layer 104 on an opposing second side of the device layer 102 may be used for power distribution in the semiconductor device 100.

The device layer 102 includes a substrate layer 106 of the semiconductor device 100. The substrate layer 106 may correspond to a portion of a semiconductor wafer on which the semiconductor device 100 is formed. The substrate layer 106 may include a silicon (Si) substrate, a substrate formed of a material including silicon, a III-V compound semiconductor material substrate such as gallium arsenide (GaAs), a silicon on insulator (SOI) substrate, or another type of substrate. The substrate layer 106 may extend in an x-direction and/or in a y-direction in the semiconductor device 100 such that the top and bottom surfaces of the substrate layer 106 are approximately orthogonal to the z-direction in the semiconductor device 100.

A dielectric layer 108 is included over the substrate layer 106. The dielectric layer 108 includes an interlayer dielectric (ILD) layer (e.g., an ILDO layer), an etch stop layer (ESL), and/or another type of dielectric layer. The dielectric layer 108 includes dielectric material(s) that enable various portions of the substrate layer 106 to be selectively etched or protected from etching, and/or may electrically isolate integrated circuit devices 110 in the device layer 102. The dielectric layer 108 includes a silicon nitride (SixNy), an oxide (e.g., a silicon oxide (SiOₓ) and/or another oxide material), and/or another type of dielectric material. The dielectric layer 108 may extend in the x-direction and/or in a y-direction in the semiconductor device 100.

The integrated circuit devices 110 may be included in and/or on the substrate layer 106, and/or in in the dielectric layer 108 in the device layer 102 of the semiconductor device 100. The integrated circuit devices 110 include transistors (e.g., planar transistors, fin field effect transistors (finFETs), nanostructure transistors such as gate all around (GAA) transistors and/or nanosheet transistors, complementary nanostructure nanostructure (CFETs)), pixel sensors, capacitors, resistors, inductors, photodetectors, transceivers, transmitters, receives, optical circuits, and/or other types of semiconductor devices.

An integrated circuit device 110 may include a plurality of source/drain regions 112 that are grown and/or otherwise formed on and/or around portions of the substrate layer 106. “Source/drain region(s)” may refer to a source or a drain, individually or collectively, dependent upon the context. The source/drain regions 112 may be formed by epitaxially growing doped semiconductor regions and/or by another semiconductor process. In some implementations, the source/drain regions 112 are formed in recessed portions in the substrate layer 106. The recessed portions may be formed by strained source/drain (SSD) etching of the substrate layer 106 and/or another type etching operation.

An integrated circuit device 110 may further include a gate dielectric layer 114 between a gate structure 116 and the substrate layer 106. In some implementations, the gate dielectric layer 114 also extends along the sidewalls of the gate structure 116. In some implementations, the gate dielectric layer 114 includes a low dielectric constant (low-k) dielectric material such as silicon oxide (SiOₓ). In some implementations, the gate dielectric layer 114 includes a high dielectric constant (high-k) dielectric material such as hafnium oxide (HfOx). A high-k dielectric material may be a dielectric material having a dielectric constant that is greater than approximately 9.

The gate structure 116 may be located laterally between the source/drain regions 112. In some implementations, the gate structure 116 is formed of a polysilicon material. In these implementations, the polysilicon material may be doped with one or more types of dopants (e.g., p-type dopants, n-type dopants) to tune a work function of the gate structure 116.

In some implementations, the gate structure 116 is formed of one or more metal materials (e.g., tungsten (W), titanium (Ti), cobalt (Co), and/or another metal. In these implementations, the gate structure 116 may include one or more work function metal layers 118 (e.g., p-type metal layers, n-type metal layers) for tuning the work function of the gate structure 116. The work function metal layer(s) 118 may be included between the gate dielectric layer 114 and the gate structure 116.

A p-type work function metal layer may include one or more p-type metals, such as tungsten (W), cobalt (Co), titanium nitride (TiN), tungsten nitride (WN), and/or another metal having a work function that is greater than approximately 4.7 electron volts (eV), among other examples. A p-type work function metal layer may be included to tune the work function of the gate structure 116 such that the work function is adjusted close to the valence band of the material of the substrate layer 106.

An n-type work function metal layer may include one or more metal materials that tune or adjust the work function of the gate structure 116 near the conduction band of the material of the substrate layer 106 of the semiconductor device 100. In some implementations, an n-type work function metal layer may include titanium aluminum (TiAl). In some implementations, an n-type work function metal layer includes titanium aluminum carbon (TiAIC). In some implementations, an n-type work function metal layer includes another aluminum-containing metal. In some implementations, another n-type metal material is included in an n-type work function metal layer.

Sidewall spacers 120 may be included on the sidewalls of the gate structure 116 to provide electrical isolation for the gate structure 116, among other examples. In some implementations, the sidewall spacers 120 are in contact with the gate dielectric layer 114. In some implementations, the sidewall spacers 120 are in contact with the work function metal layer 118. In some implementations, the sidewall spacers 120 are in direct contact with the gate structure 116. The sidewall spacers 120 may include a silicon oxide (SiOₓ), a silicon nitride (SixNy), a silicon oxycarbide (SiOC), a silicon oxycarbonitride (SiOCN), and/or another suitable material. In some implementations, the dielectric material of the sidewall spacers 120 may have a dielectric constant that is less than the dielectric constant of the dielectric material of the gate dielectric layer 114.

The source/drain regions 112 are electrically coupled and/or physically coupled to source/drain contact structures 122. The source/drain contact structures 122 may include contact vias, contact plugs, and/or another type of contact structures that electrically connect the source/drain regions 112 of the integrated circuit devices 110 with the interconnect layer 104 of the semiconductor device 100. The source/drain contact structures 122 include cobalt (Co), ruthenium (Ru), tungsten (W), molybdenum (Mo), copper (Cu), and/or another electrically conductive material or metal material. One or more liner layers 124 may be included on sidewalls of the source/drain contact structures 122. The liner layer(s) 124 may include a barrier layer that is included to prevent or minimize diffusion of materials from the source/drain contact structures 122 to the surrounding dielectric layers, an adhesion layer or glue layer that is included to promote adhesion between the source/drain contact structures 122 and the surrounding dielectric layers, and/or another type of liner. Examples of materials for the liner layer(s) 124 include titanium nitride (TiN), tantalum nitride (TaN), and/or another suitable liner material.

The interconnect layer 104 of the semiconductor device 100 is included above the substrate layer 106 and above the integrated circuit devices 110 in the z-direction in the semiconductor device 100. The interconnect layer 104 includes a plurality of dielectric layers that are arranged in a direction (e.g., the z-direction) that is approximately perpendicular to the substrate layer 106. The dielectric layers may include ILD layers 126 and ESLs 128 that are arranged in an alternating manner in the z-direction. The ILD layers 126 and the ESLs 128 may extend in the x-direction and/or in the y-direction in the semiconductor device 100.

The ILD layers 126 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 126 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 128 may each include a silicon nitride (SiₓN_{y}), silicon carbide (SiC), silicon oxynitride (SiON), and/or another suitable dielectric material. In some implementations, an ILD layer 126 and an ESL 128 include different dielectric materials to provide etch selectivity to enable various structures to be formed in the interconnect layer 104.

The interconnect layer 104 includes a plurality of backend conductive structures that are arranged in a plurality of layers. The backend conductive structures may be electrically coupled and/or physically coupled to one or more of the integrated circuit devices 110 in the device layer 102. The backend conductive structures provide electrical routing that enables signals and/or power to be provided to and/or from the integrated circuit devices 110.

The layers of backend conductive structures may include a plurality of layers 130a-130e that are vertically arranged and alternate with a plurality of layers 132a-132e in the z-direction (e.g., vertically alternate). The layers 130a-130e each include a layer of interconnect structures, and the layers 132a-132e each include a layer of metallization structures. The layers 130a-130e of interconnect structures may be referred to as V-layers. The layers 132a-132e of metallization structures may be referred to as M-layers.

As shown in FIG. 1, a layer 130a of interconnect structures may be a bottom-most layer of interconnect structures in the interconnect layer, and may be referred to as a via-0 (V0) layer. The interconnect structures of the layer 130a may include source/drain interconnect structures 134 that are electrically coupled and/or physically coupled to the source/drain contact structures 122, and gate interconnect structures 136 that are electrically coupled and/or physically coupled to the gate structures 116. In some implementations, gate contacts (not shown) are included between the gate structures 116 and the gate interconnect structures 136. In some implementations, the source/drain interconnect structures 134 are referred to source/drain vias (VDs), and the gate interconnect structures 136 are referred to as gate vias (VGs).

The source/drain interconnect structures 134 and the gate interconnect structures 136 may each include vias, conductive pillars, conductive columns, and/or another type of electrically conductive structures that are elongated in the z-direction. The source/drain interconnect structures 134 and the gate interconnect structures 136 may each include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials. In some implementations, the source/drain interconnect structures 134 and the gate interconnect structures 136 include the same material(s). In some implementations, the source/drain interconnect structures 134 include material(s) that are different from the material(s) of the gate interconnect structures 136. In some implementations, one or more liner layers are included between the surrounding dielectric layers in the interconnect layer 104. The source/drain interconnect structures 134 and the gate interconnect structures 136 may be located in an ILD layer 126 and/or in an ESL 128.

In some implementations, one or more liner layers be included between these layers and the source/drain interconnect structures 134 and the gate interconnect structures 136. The liner layer(s) may each include may include barrier liners, adhesion liners, and/or another type of liners. Examples of materials for the one or more liners include tantalum nitride (TaN) and/or titanium nitride (TiN), among other examples.

In some implementations, the source/drain interconnect structures 134 and the gate interconnect structures 136 are liner-free. In these implementations, the source/drain interconnect structures 134 and the gate interconnect structures 136 may be formed using a bottom-up deposition technique. The bottom-up deposition technique may include selectively depositing the material of the source/drain interconnect structures 134 and the gate interconnect structures 136 on the source/drain contacts 122 and on the gate structures 116, respectively. In this way, the material of the source/drain interconnect structures 134 and the gate interconnect structures 136 accumulates (e.g., “grows”) from the bottoms of the recesses in which the source/drain interconnect structures 134 and the gate interconnect structures 136 are formed, as opposed to the material accumulating on the sidewalls as well as on the bottoms of the recesses. The bottom-up growth of the source/drain interconnect structures 134 and the gate interconnect structures 136 enables the source/drain interconnect structures 134 and the gate interconnect structures 136 to be formed seam-free. The absence of seams in the source/drain interconnect structures 134 and the gate interconnect structures 136 occurs due to the bottom-up growth, whereas seams might otherwise occur where material is accumulated on the sidewalls of the recesses (which might merge at the top of the recesses before the recesses can be fully filled in with the material of the source/drain interconnect structures 134 and the gate interconnect structures 136).

As further shown in FIG. 1, a layer 132a of metallization structures may be a bottom-most layer of metallization structures in the interconnect layer, and may be referred to as a metal-0 (M0) layer. The metallization structures in the layer 132a (e.g., the M0 layer) may located above and coupled to the source/drain interconnect structures 134 and the gate interconnect structures 136 in the layer 130a (e.g., the V0 layer).

The metallization structures in the layer 132a may be formed from a barrier layer 138 and a metal layer 140. The barrier layer 138 may be located above and/or on the ILD layer 126 of the layer 130a, and the metal layer 140 may be located above and/or on the barrier layer 138. The barrier layer 138 may include a tantalum nitride (TaN) barrier layer and/or titanium nitride (TiN) barrier layer, among other examples. The barrier layer 138 may be included between the metal layer 140 and the source/drain interconnect structures 134 and the gate interconnect structures 136 in the layer 130a to prevent, minimize, and/or otherwise reduce the diffusion of material from the source/drain interconnect structures 134 and the gate interconnect structures 136 upward into the metal layer 140.

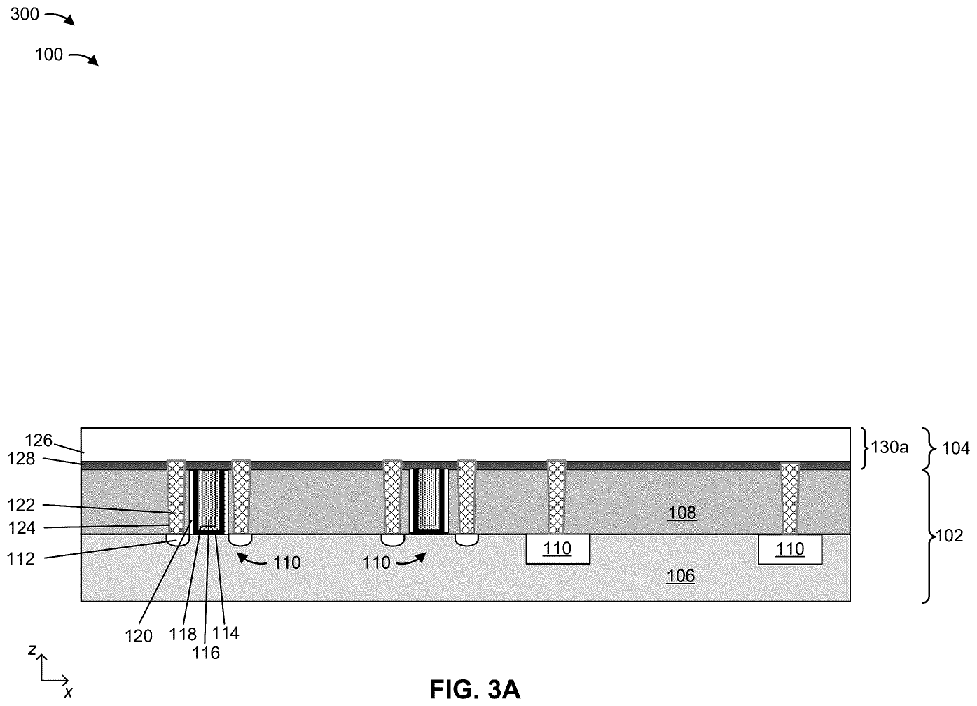

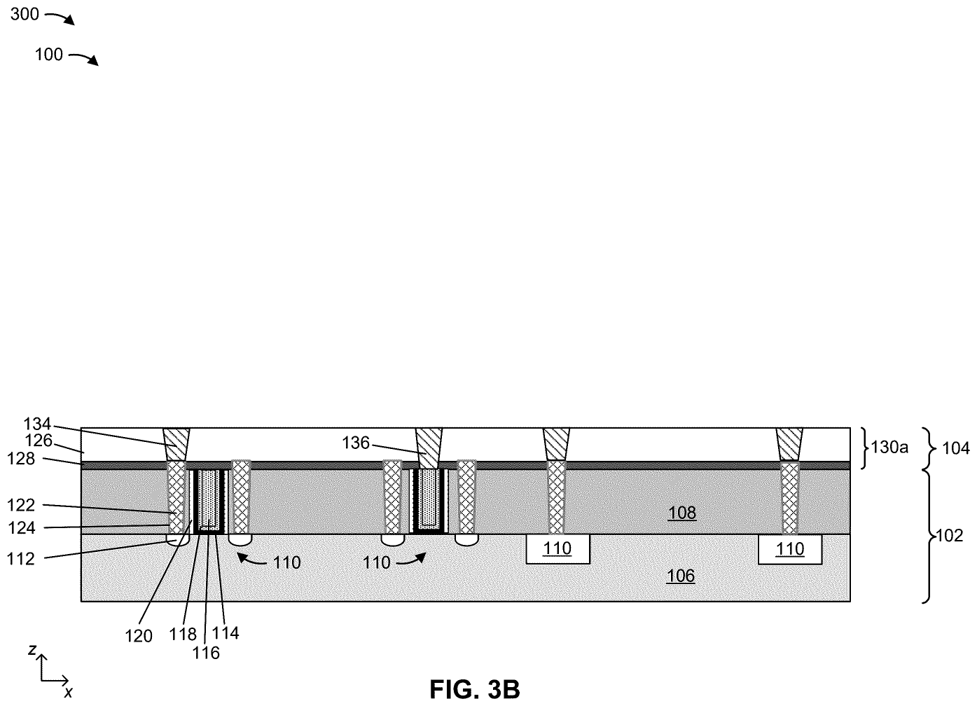

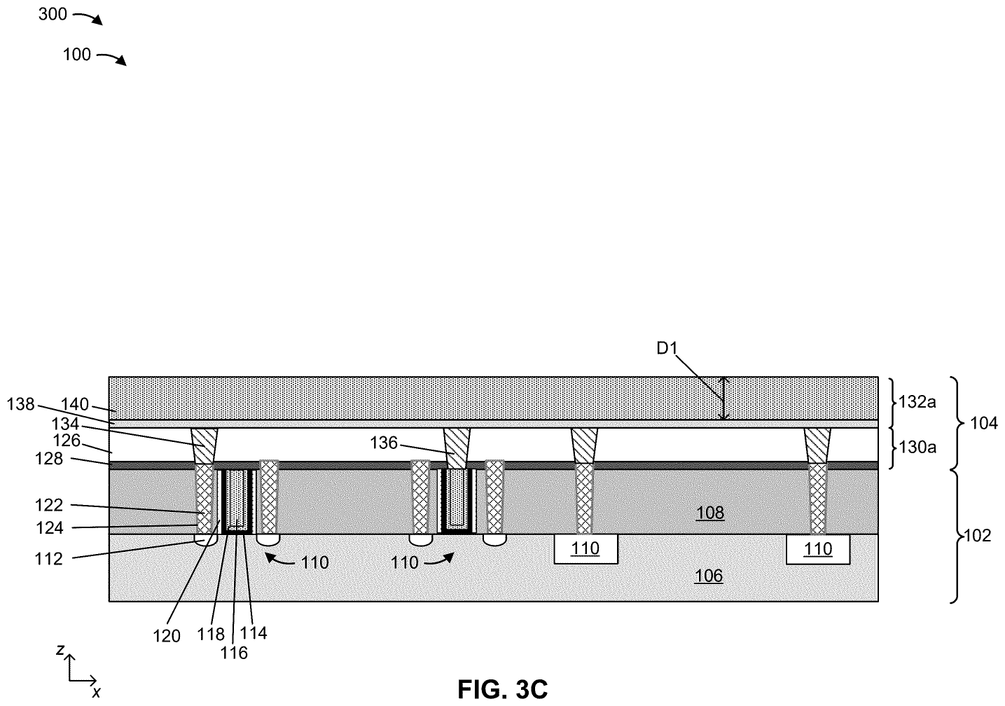

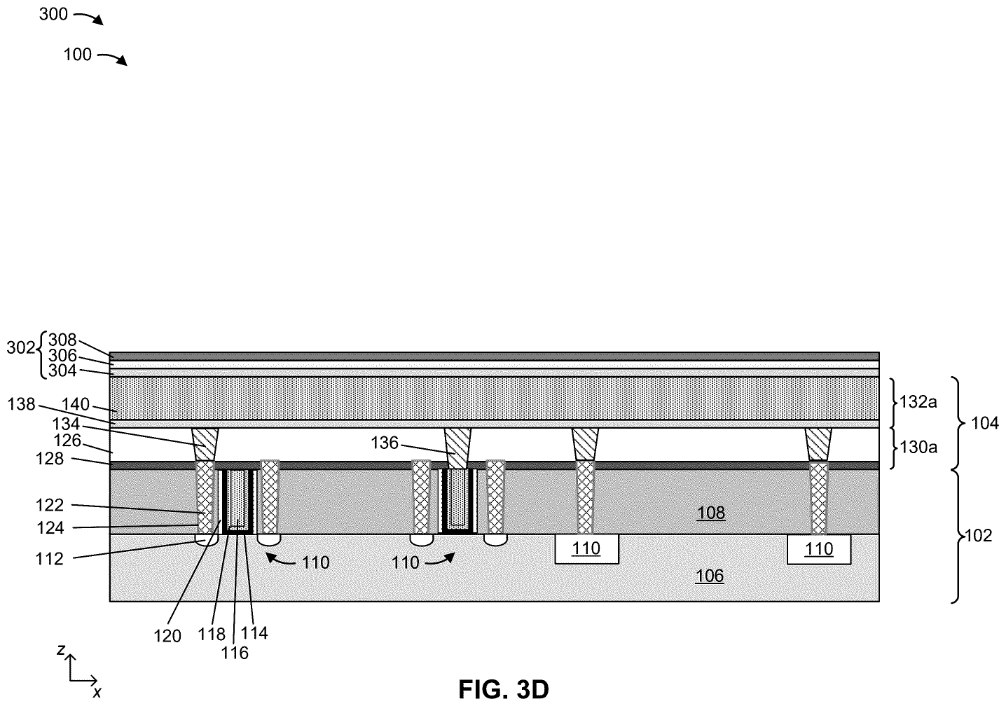

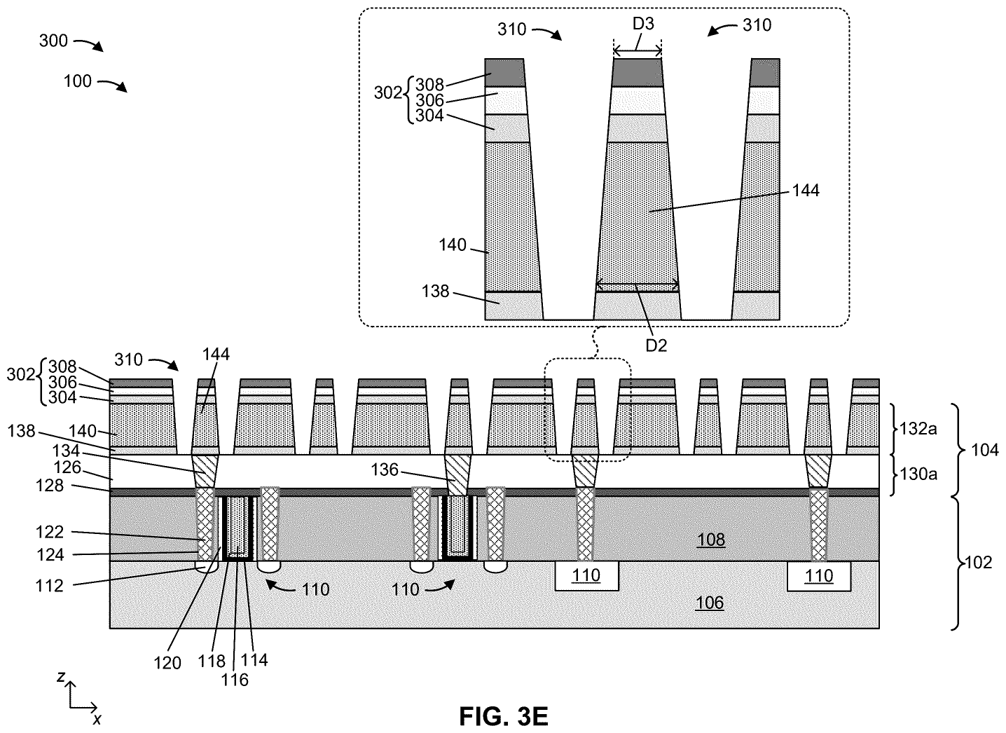

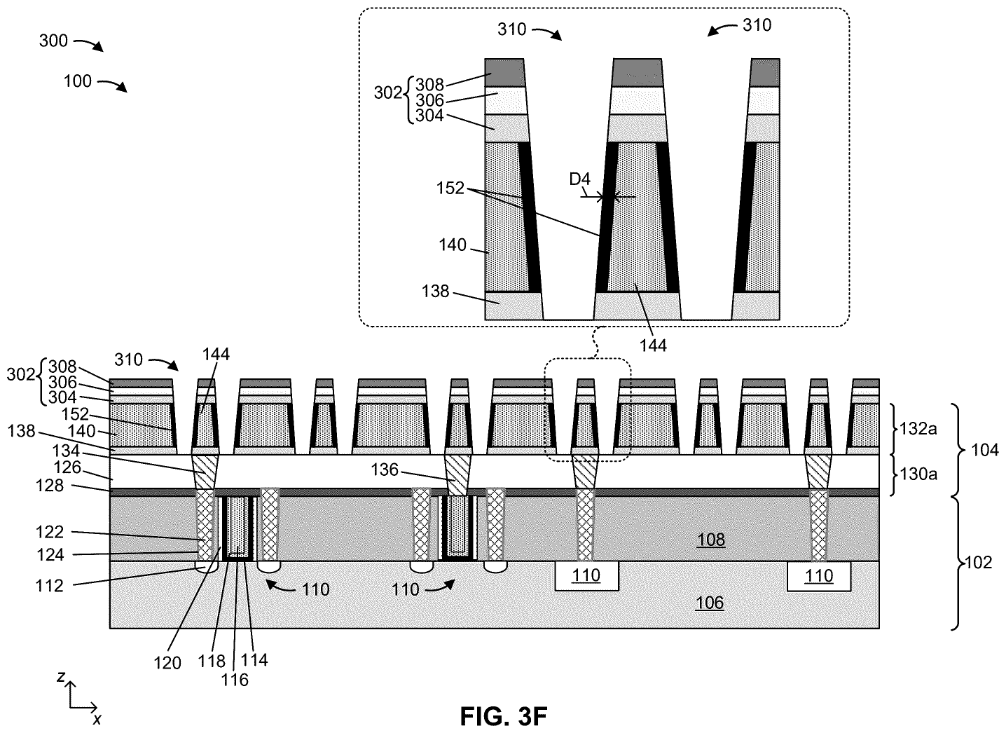

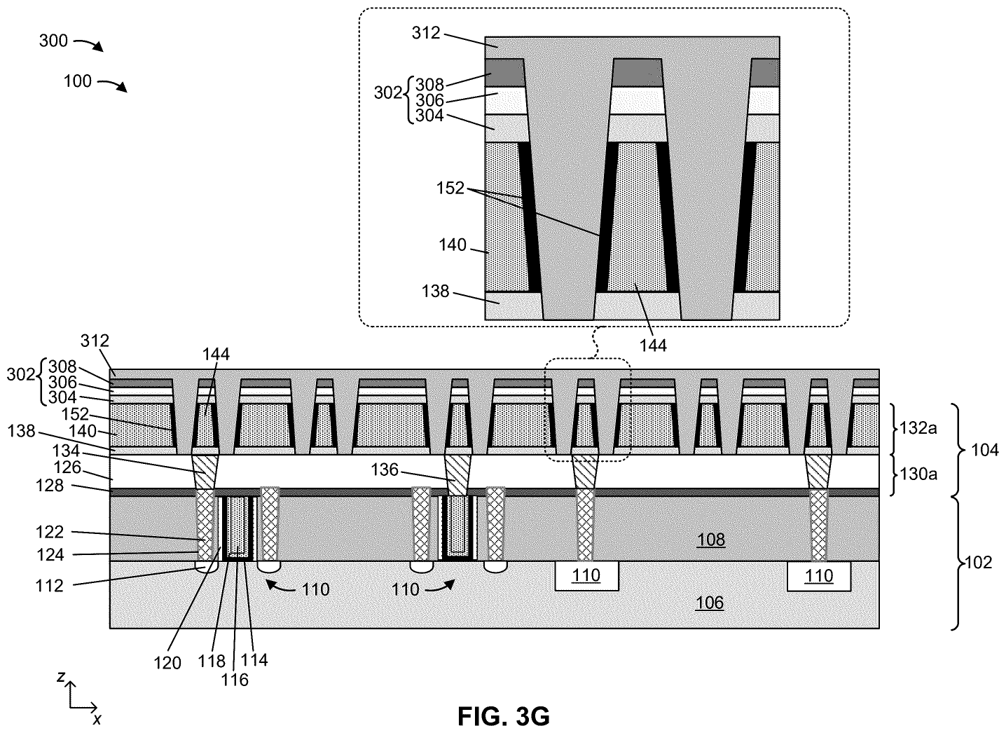

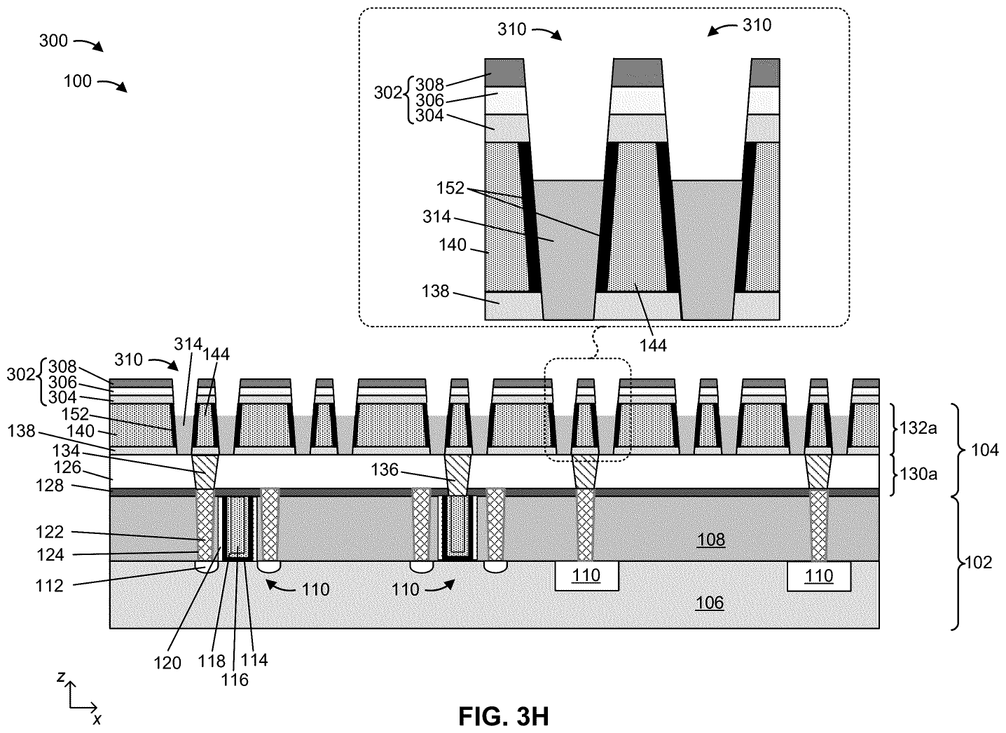

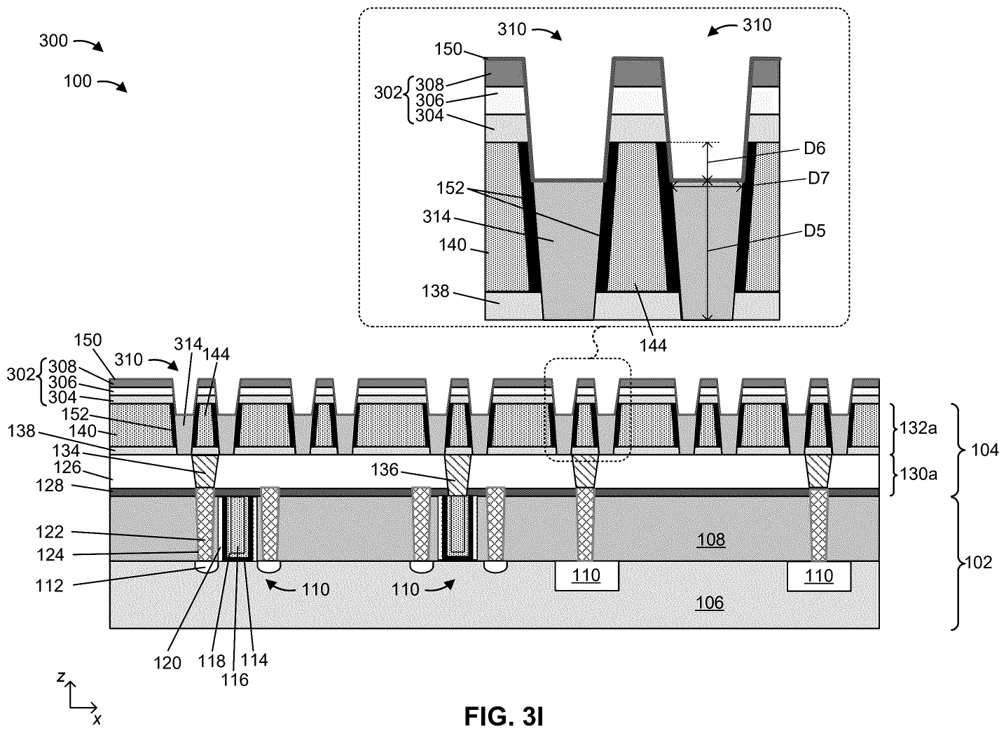

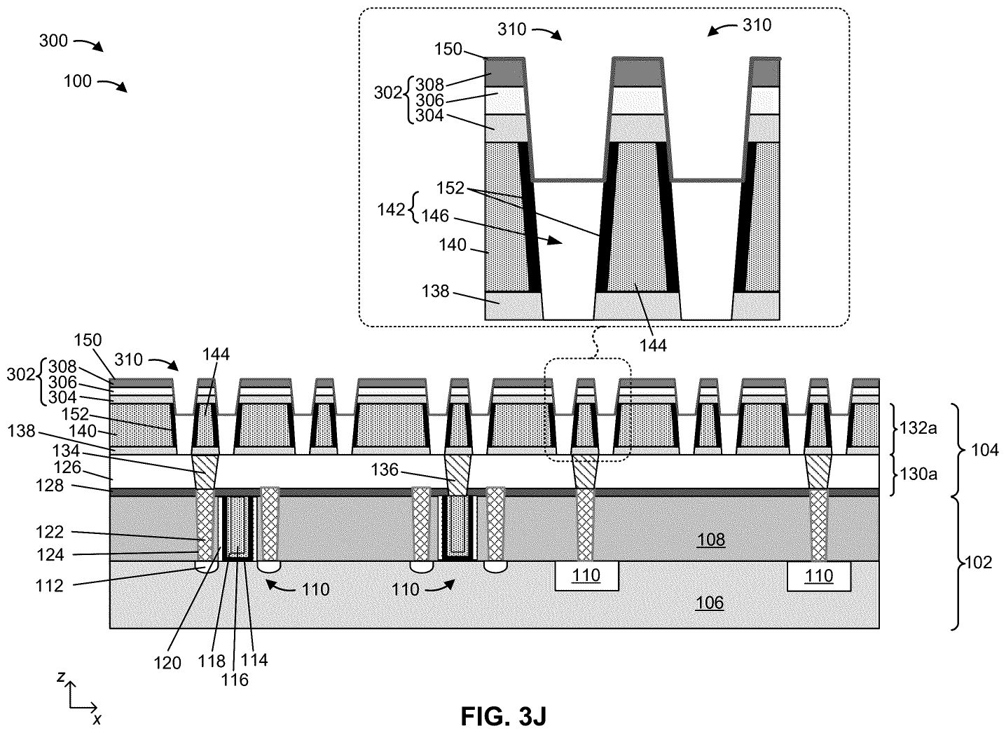

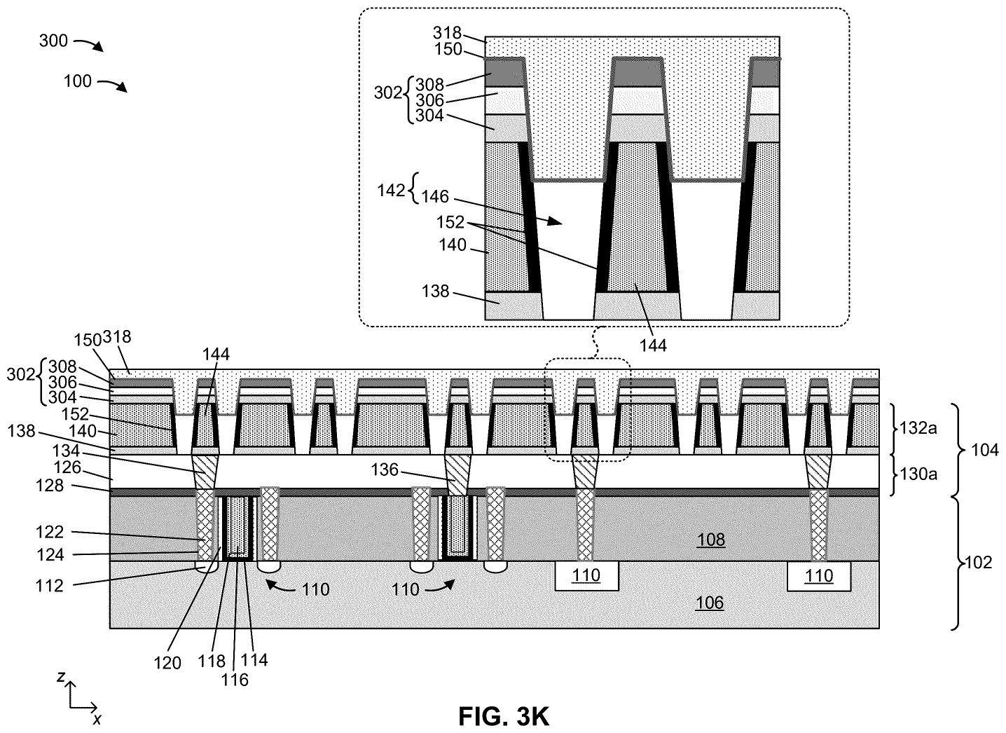

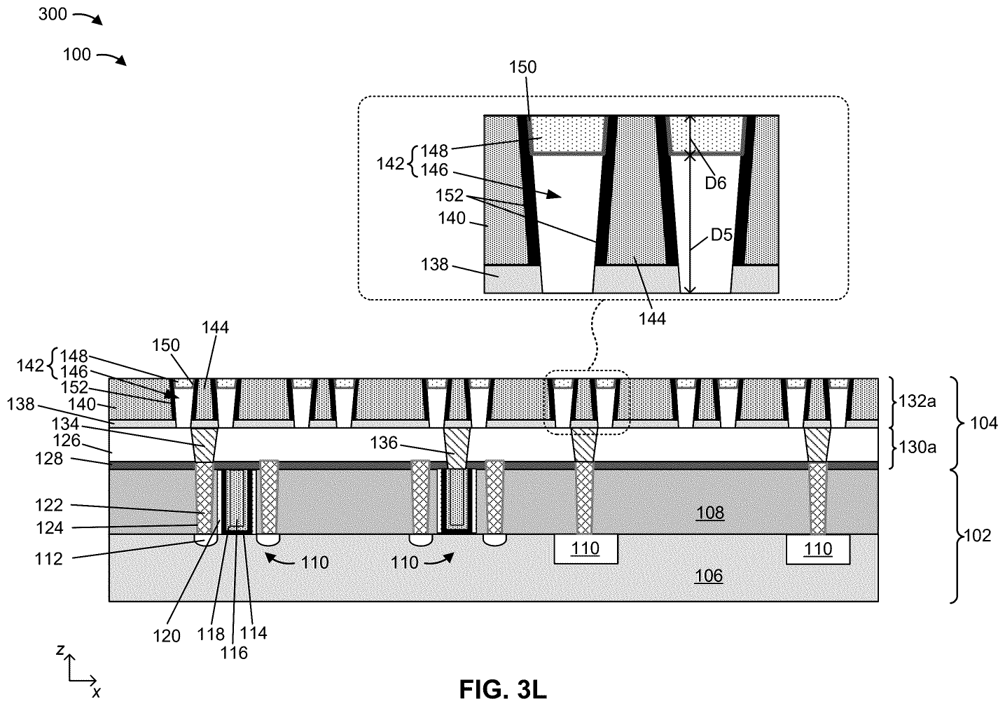

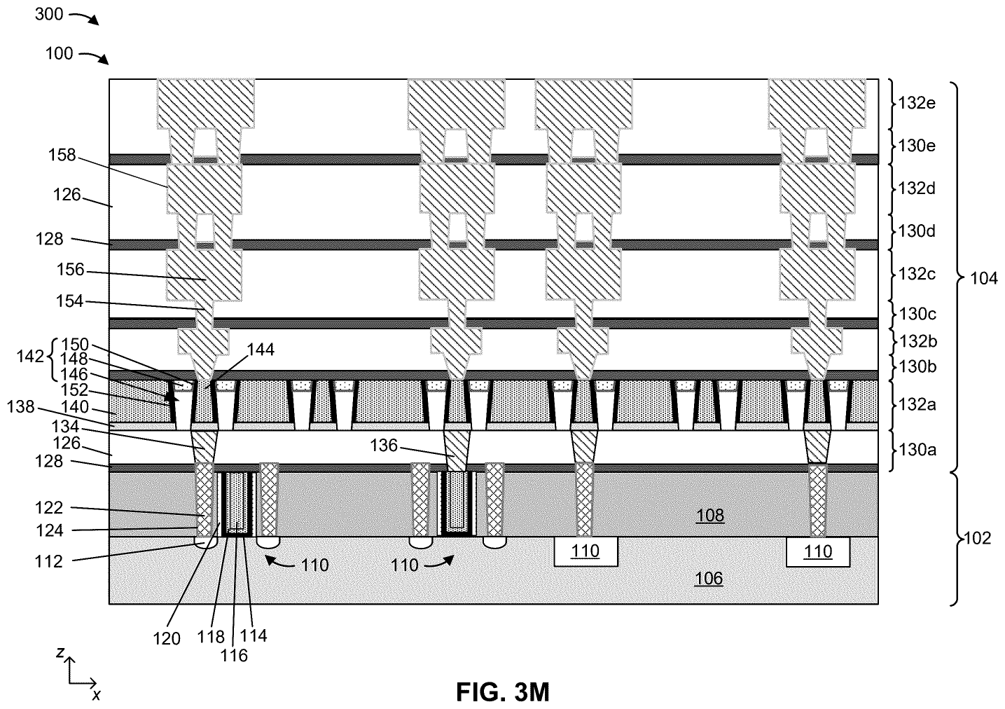

The metal layer 140 may include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials. As described in connection with FIGS. 3A-3M, the metal layer 140 may be patterned and etched to form isolation regions 142 in the metal layer 140. The isolation regions 142 vertically extend through the metal layer 140 and the barrier layer 138, and define metallization structures 144 of the layer 132a of metallization structures.

As shown in FIG. 1, the metallization structures 144 may have an inverted cross-sectional profile relative to the source/drain interconnect structures 134 and the gate interconnect structures 136 in the layer 130a of interconnect structures. In particular, the top widths of the metallization structures 144 may be less than the bottom widths of the metallization structures 144, whereas the top widths of the source/drain interconnect structures 134 and the gate interconnect structures 136 may be greater than the bottom widths of the source/drain interconnect structures 134 and the gate interconnect structures 136 in the layer 130a. This occurs because of the different processes and techniques used to form the layers 130a and 132a. For example, and as described in more detail in connection with FIGS. 3A-3M, the source/drain interconnect structures 134 and the gate interconnect structures 136 in the layer 130a may be formed by forming the ESL 128 and the ILD 126 of the layer 130a, etching these layers to form recesses through these layers, and forming the source/drain interconnect structures 134 and the gate interconnect structures 136 in the recesses. In contrast, and as described in more detail in connection with FIGS. 3A-3M, the barrier layer 138 and the metal layer 140 are formed and then etched to form the isolation regions 142 that define the metallization structures 144. Thus, the isolation regions 142 have a similar cross-sectional profile as the source/drain interconnect structures 134 and the gate interconnect structures 136.

An isolation region 142 may include an air spacer 146 defined by the barrier layer 138 and the metal layer 140, and that is sealed at the top of the air spacer 146 by a dielectric plug 148. The dielectric plug 148 may include a low-k dielectric material such as a silicon oxide (SiO₂). The low-k dielectric material of the dielectric plug 148, along with the air of the air spacer 146, enables a low parasitic capacitance to be achieved between metallization structures 144 electrically isolated by the isolation region 142. However, other dielectric materials may be used for the dielectric plug 148.

An isolation region 142 may include a supporting layer 150 that is formed during the process of forming the air spacers 146 and the dielectric plugs 148 of the isolation regions 142. The supporting layers 150 may include a conformal layer that supports the material of the dielectric plugs 148 as the material is deposited, so as to prevent the material of the dielectric plugs 148 from filling in the air spacers 146. The supporting layer 150 may include a dielectric material. For example, the supporting layer 150 may include an oxide material such as a silicon oxide-based material. Examples of such materials include silicon dioxide (SiO₂), silicon oxycarbide (SiOC), silicon oxynitride (SiON), and/or silicon oxycarbonitride (SiOCN), among other examples.

As further shown in FIG. 1, sidewalls of the metallization structures 144 facing the isolation regions 142 may correspond to metal-oxide liners 152. The metal-oxide liners 152 are parts of the sidewalls of the metallization structures 144 that were exposed through air spacers 146 that were formed during the process for forming the isolation regions 142. With the recesses opened, the sidewalls of the metallization structures 144 were oxidized to form the metal-oxide liners 152. Thus, the metal-oxide liners 152 may include an oxide of the metal of the metal layer 140. For example, the metal layer 140 may include ruthenium (Ru), and the metal-oxide liners 152 may include ruthenium oxide (RuOₓ such as ruthenium dioxide (RuO₂)). The ruthenium of the metal layer 140 corresponding to the main body of the metallization structures 144 may have a polycrystalline structure, whereas the ruthenium oxide material of the metal-oxide liners 152 may have a monocrystalline structure. As another example, the metal layer 140 may include cobalt (Co), and the metal-oxide liners 152 may include cobalt oxide (CoOₓ such as CoO₂). An example of this process is described in greater detail in connection with FIGS. 3A-3M.

Etching the metal layer 140 to define the metallization structures 144 enables the metallization structures 144 to be more closely spaced together than if the metallization structures 144 were formed in recesses in a dielectric layer, and the metal-oxide liners 152 provide increased strength for the metallization structures 144 to reduce the likelihood of collapse of the metallization structures 144 (which might otherwise occur because of the reduced size of the metallization structures 144) before the air spacers 146 were sealed with the dielectric plugs 148. The increased mechanical strength may be provided by the monocrystalline structure of the metal-oxide liners 152 in that the monocrystalline structure of the metal-oxide liners 152 may have a higher mechanical strength relative to the polycrystalline structure of the main body of the metallization structures 144 because the absence of grain boundaries in the monocrystalline structure provides for more uniform stress distribution and resistance to deformation.

Moreover, the metal-oxide liners 152 may have a low electrical resistivity that is close to the electrical resistivity of the metal material of the metallization structures 144, and therefore has minimal impact on the overall resistance of the metallization structures 144. For example, if the main body of the metallization structures 144 is formed of ruthenium (Ru), the main body of the metallization structures 144 may have an electrical resistivity that is included in a range of approximately 1 micro Ohm centimeter to approximately 10 micro Ohms centimeter. The metal-oxide liners 152 (which correspond to the sidewalls of the metallization structures 144) may be formed of ruthenium oxide, which may have an electrical resistivity that is included in a range of approximately 20 micro Ohms centimeter to approximately 50 micro Ohms centimeter. However, other values and ranges are within the scope of the present disclosure.

As further shown in FIG. 1, a layer 130b (e.g., a via-1 (V1) layer) of interconnect structures 154 may be included above and electrically coupled to the layer 132a (e.g., the M0 layer). A layer 132b (e.g., a metal-1 (M1) layer) of metallization structures 156 may be located above and electrically coupled to the layer 130b (e.g., the V1 layer) in the interconnect layer 104. A layer 130c (e.g., a via-2 (V2) layer) of interconnect structures 154 may be included above and electrically coupled to the layer 132b (e.g., the M1 layer). A layer 132c (e.g., a metal-2 (M2) layer) of metallization structures 154 may be located above and electrically coupled to the layer 130c (e.g., the V2 layer) in the interconnect layer 104. A layer 130d (e.g., a via-3 (V3) layer) of interconnect structures 154 may be included above and electrically coupled to the layer 132c (e.g., the M2 layer). A layer 132d (e.g., a metal-3 (M3) layer) of metallization structures 156 may be located above and electrically coupled to the layer 130d (e.g., the V3 layer) in the interconnect layer 104. A layer 130e (e.g., a via-4 (V4) layer) of interconnect structures 154 may be included above and electrically coupled to the layer 132d (e.g., the M3 layer). A layer 132e (e.g., a metal-4 (M4) layer) of metallization structures 156 may be located above and electrically coupled to the layer 130e (e.g., the V4 layer) in the interconnect layer 104.

In some implementations, the interconnect structures may include a different quantity of (e.g., greater, fewer) layers 130a-130e of interconnect structures (e.g., V-layers) and/or may include a different quantity of (e.g., greater, fewer) layers 132a-132e of metallization structures (e.g., M-layers) than shown in the example in FIG. 1.

The interconnect structures 154 may include a combination of vias, interconnects, and/or other types of conductive structures. The metallization structures 156 may include a combination of trenches, metallization layers, conductive traces, and/or other types of conductive structures. The interconnect structures 154 and the metallization structures 156 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers 158 are included between the dielectric layers of the interconnect layer 104 and the interconnect structures 154, and/or between the dielectric layers of the interconnect layer 104 the metallization structures 156. The one or more liner layers 158 may include barrier liners, adhesion liners, and/or another type of liners. Examples of materials for the one or more liners 158 include tantalum nitride (TaN) and/or titanium nitride (TiN), among other examples. In some implementations, the electrical conductivity of the material (e.g., TaN) of one or more liners 158 may be less than the electrical conductivity of the material of the metal-oxide liners 152 (e.g., ruthenium oxide (RuOₓ).

In some implementations, the topmost layer of backend conductive structures (e.g., a topmost layer of metallization structures 156, a topmost layer of interconnect structures 154) may be coupled to connection structures at the top of the semiconductor device 100. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of backend conductive structures (e.g., a topmost layer of metallization structures 156, a topmost layer of interconnect structures 154) may be coupled to bonding structures, such as bonding pads and/or bonding vias.

As indicated above, FIG. 1 is provided as an example. Other examples may differ from what is described with regard to FIG. 1.

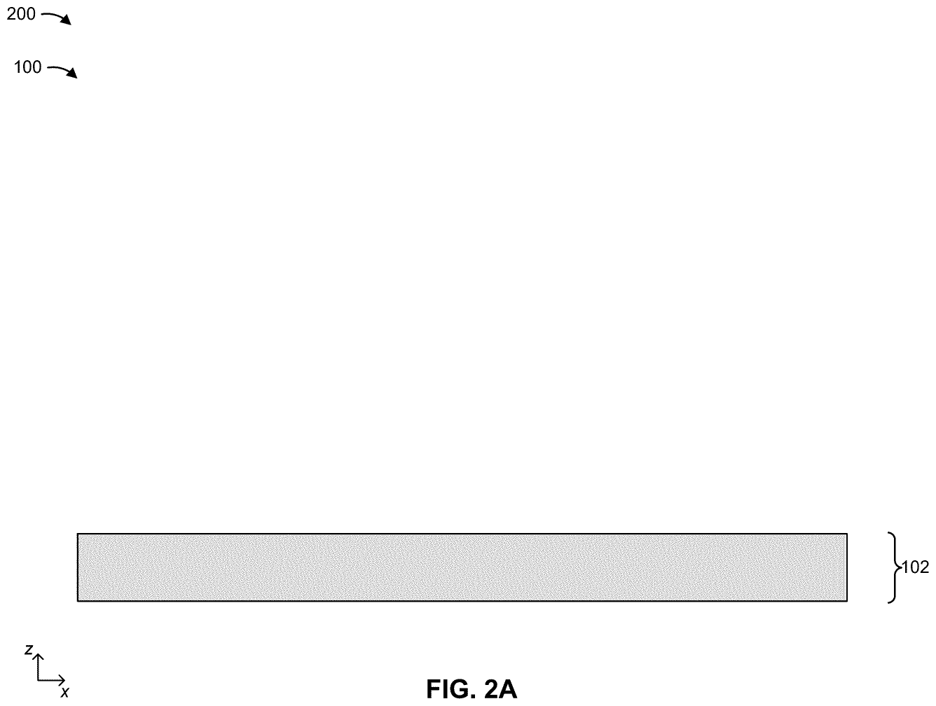

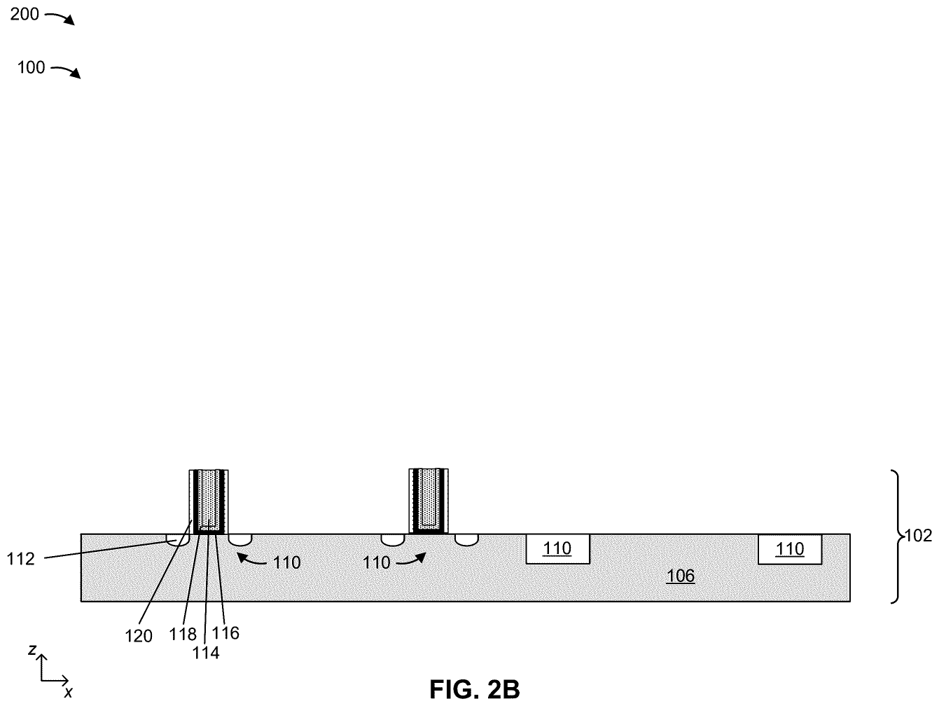

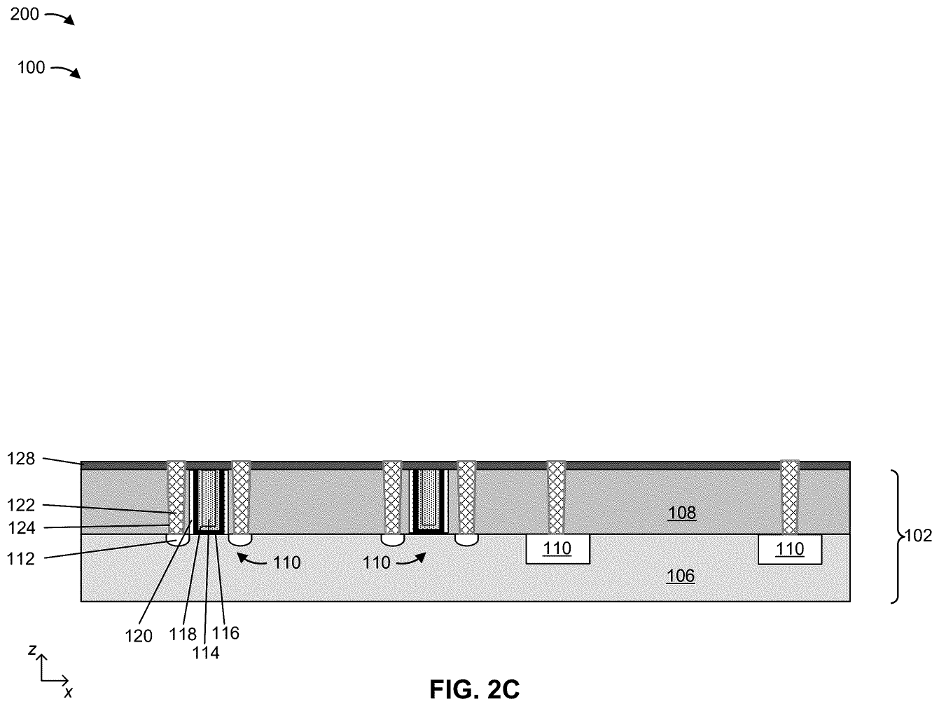

FIGS. 2A-2C are diagrams of an example implementation 200 of forming a portion of the semiconductor device 100 described herein. In particular, the example implementation 200 includes an example of forming the device layer 102 (e.g., the front end region or FEOL region) of the semiconductor device 100. In some implementations, one or more of the semiconductor processing operations described in connection with FIGS. 2A-2C may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 2A, the substrate layer 106 is provided. The substrate layer 106 may be provided in the form of a semiconductor wafer such as a silicon (Si) wafer, a silicon-on-insulator (SOI) wafer, and/or another type of semiconductor work piece. The semiconductor device 100 may be formed on the semiconductor wafer with other semiconductor devices.

As shown in FIG. 2B, the integrated circuit devices 110 may be formed in and/or on the substrate layer 106 of the device layer 102 of the semiconductor device 100. One or more semiconductor processing tools may be used to form one or more portions of the integrated circuit devices 110. For example, an ion implantation tool may be used to dope one or more regions in the substrate layer 106 with one or more types of dopants to form source/drain regions 112 in the substrate layer 106 for the integrated circuit devices 110. As another example, a deposition tool may be used to perform various deposition operations to deposit layers and/or structures of the integrated circuit devices 110, and/or to deposit photoresist layers for etching the substrate layer 106 and/or portions of the deposited layers. Such layers may include gate dielectric layers 114, gate structures 116, and/or work function metal layers 118, among other examples.

As in FIG. 2C, a deposition tool is used to deposit the dielectric layer 108 over and/or on the substrate layer 106 and over and/or on the integrated circuit devices 110, and an ESL 128 over and/or on the dielectric layer 108. A deposition tool may be used to deposit the dielectric layer 108 and the ESL 128 each using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 108 and/or the ESL 128 after the dielectric layer 108 and/or the ESL 128 is deposited.

As further shown in FIG. 2C, the source/drain contact structures 122 of the integrated circuit devices 110 may be formed through the dielectric layer 108 and the ESL 128. The source/drain contact structures 122 may be formed in recesses in the dielectric layer 108 and in the ESL 128. In some implementations, a pattern in a photoresist layer is used to etch the dielectric layer 108 and/or the ESL 128 to form the recesses. In these implementations, a deposition tool may be used to form the photoresist layer on the ESL 128. An exposure tool may be used to expose the photoresist layer to a radiation source to pattern the photoresist layer. A developer tool may be used to develop and remove portions of the photoresist layer to expose the pattern. An etch tool may be used to etch the dielectric layer 108 and/or the ESL 128 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 108 based on a pattern to form the recesses.

The source/drain contact structures 122 may be formed in the recesses such that the source/drain contact structures 122 land on the source/drain regions 112. A deposition tool may be used to deposit the material of the source/drain contact structures 122 in the recesses using a CVD technique, a PVD technique, an ALD technique, an electroplating technique, and/or another suitable deposition technique. The material of the source/drain contact structures 122 may be deposited in one or more deposition operations. In some implementations, a seed layer is first deposited, and the material of the source/drain contact structures 122 is deposited on the seed layer. In some implementations, one or more liner layers 124 are deposited in the recesses, and the source/drain contact structures 122 are deposited on the liner layer(s) 124. In some implementations, a planarization tool is used to perform a planarization operation (e.g., a CMP operation) to planarize the source/drain contact structures 122 after the source/drain contact structures 122 are deposited such that the tops of the source/drain contact structures 122 are approximately co-planar with the top of the ESL 128.

As indicated above, FIGS. 2A-2C are provided as an example. Other examples may differ from what is described with regard to FIGS. 2A-2C.

FIGS. 3A-3M are diagrams of an example implementation 300 of forming a portion of the semiconductor device 100 described herein. In particular, the example implementation 300 includes an example of forming the interconnect layer 104 (e.g., the back end region or BEOL region) of the semiconductor device 100. In some implementations, one or more of the semiconductor processing operations described in connection with FIGS. 3A-3M may be performed after one or more processes described in connection with FIGS. 2A-2C. In some implementations, one or more of the semiconductor processing operations described in connection with FIGS. 3A-3M may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 3A, the interconnect layer 104 of the semiconductor device 100 is formed above the dielectric layer 108 of the device layer 102. The layer 130a of interconnect structures (e.g., the bottom-most layer of interconnect structures of the interconnect layer 104) may be formed above and/or on the dielectric layer 108. To form the layer 130a, an ESL 128 may be formed over and/or on the dielectric layer 108 such that the ESL 128 covers the gate structures 116 and the source/drain contact structures 122 of the integrated circuit devices 110. An ILD layer 126 may be formed over and/or on the ESL 128.

A deposition tool may be used to deposit the ESL 128 and/or the ILD layer 126 using a PVD technique, an ALD technique, a CVD technique, an oxidation technique, and/or another suitable deposition technique. The ESL 128 and/or the ILD layer 126 may be deposited in one or more deposition operations. In some implementations, a planarization tool may be used to perform a planarization operation (e.g., a CMP operation) to planarize the ESL 128 and/or the ILD layer 126 after the ESL 128 and/or the ILD layer 126 is deposited.

As shown in FIG. 3B, the source/drain interconnect structures 134 and/or the gate interconnect structures 136 of the layer 130a of interconnect structures (e.g., the V0 layer) may be formed in and/or through the ILD layer 126 and the ESL 128. To form the source/drain interconnect structures 134 and/or the gate interconnect structures 136, recesses may be formed in and/or through the ILD layer 126 and the ESL 128. In some implementations, one or more recesses may be formed above one or more source/drain contact structures 122 such that the one or more source/drain contact structures 122 are exposed through the recesses. In some implementations, one or more recesses may be formed above one or more gate structures 116 such that the one or more gate structures 116 are exposed through the recesses.

In some implementations, a pattern in a photoresist layer is used to etch the ILD layer 126 and/or the ESL 128 of the layer 130a to form the recesses. In these implementations, a deposition tool may be used to form the photoresist layer on the ILD layer 126 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the ILD layer 126 and/or the ESL 128 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses based on a pattern.

The source/drain interconnect structures 134 and/or the gate interconnect structures 136 of the layer 130a of interconnect structures may be formed in the recesses. A deposition tool may be used to deposit the source/drain interconnect structures 134 and/or the gate interconnect structures 136 using a CVD technique, a PVD technique, an ALD technique, an electroplating technique, and/or another suitable deposition technique. The source/drain interconnect structures 134 and/or the gate interconnect structures 136 may be deposited in one or more deposition operations. In some implementations, a seed layer is first deposited, and the source/drain interconnect structures 134 and/or the gate interconnect structures 136 are deposited on the seed layer. In some implementations, a planarization tool is used to perform a planarization operation (e.g., a CMP operation) to planarize the source/drain interconnect structures 134 and/or the gate interconnect structures 136 after the source/drain interconnect structures 134 and/or the gate interconnect structures 136 are deposited.

As shown in FIGS. 3C-3L, the layer 132a of metallization structures (e.g., the M0 layer) of the interconnect layer 104 may be formed above the layer 130a of interconnect structures. As shown in FIG. 3C, the barrier layer 138 of the layer 132a may be formed over and/or on the ILD layer 126 such that the barrier layer 138 covers the source/drain interconnect structures 134 and/or the gate interconnect structures 136. The metal layer 140 of the layer 132a may be formed over and/or on the barrier layer 138.

A deposition tool may be used to deposit the barrier layer 138 using a CVD technique, a PVD technique, an ALD technique, and/or another suitable deposition technique. In some implementations, a planarization tool is used to perform a planarization operation (e.g., a CMP operation) to planarize the barrier layer 138 after the barrier layer 138 is deposited.

A deposition tool may be used to deposit the metal layer 140 using a CVD technique, a PVD technique, an ALD technique, an electroplating technique, and/or another suitable deposition technique. In some implementations, a planarization tool is used to perform a planarization operation (e.g., a CMP operation) to planarize the metal layer 140 after the metal layer 140 is deposited. The metal layer 140 may have an as-deposited polycrystalline structure. In some implementations, the metal layer 140 is deposited to a thickness (indicated in FIG. 3C as a dimension D1) that is included in a range of approximately 15 nanometers to approximately 45 nanometers. However, other values and ranges are within the scope of the present disclosure.

As shown in FIG. 3D, a patterning stack 302 may be formed over and/or on the metal layer 140. The patterning stack 302 may include one or more patterning layers 304-308. The patterning layers 304-308 may include different materials to enable a pattern to be formed in the patterning stack 302 and used to etch the metal layer 140 to define the metallization structures 144 of the layer 132a. In some implementations, the patterning layer 304 may include a titanium nitride (TiN) layer, the patterning layer 306 may include a silicon nitride (SiₓN_{y}) layer, and/or the patterning layer 308 may include a silicon oxide (SiOₓ) layer. However, other combinations of materials for the patterning layers 304-308 are within the scope of the present disclosure.

A deposition tool may be used to deposit the patterning layers 304-308 of the patterning stack 302 using a CVD technique, a PVD technique, an ALD technique, an oxidation technique, and/or another suitable deposition technique. In some implementations, a planarization tool is used to perform a planarization operation (e.g., a CMP operation) to planarize the patterning layer 304, the patterning layer 306, and/or the patterning layer 308 after the patterning layer 304, the patterning layer 306, and/or the patterning layer 308 is deposited.

As shown in FIG. 3E, the patterning layers 304-308 of the patterning stack 302 may be used to form recesses 310 through the metal layer 140 and through the barrier layer 138 to define the metallization structures 144 of the layer 132a of metallization structures. In some implementations, a recess 310 is formed adjacent to and/or around a source/drain interconnect structure 134 to define a metallization structure 144 above and/or on the source/drain interconnect structure 134. In some implementations, a recess 310 is formed adjacent to and/or around a gate interconnect structure 136 to define a metallization structure 144 above and/or on the gate interconnect structure 136.

In some implementations, a pattern in a photoresist layer is used to etch the patterning layers 304-308 of the patterning stack 302 to transfer the pattern to the patterning layers 304-308 of the patterning stack 302. In these implementations, a deposition tool may be used to form the photoresist layer on the patterning stack 302 (e.g., on the patterning layer 308) (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the patterning layers 304-308 of the patterning stack 302 based on the pattern to transfer the pattern to the patterning stack 302.

The pattern transferred to the patterning layers 304-308 of the patterning stack 302 may be used to etch the metal layer 140 and the barrier layer 138 to form the recesses 310. In some implementations, the etch operation includes a dry etch operation (e.g., a plasma-based etch operation, a gas-based etch operation), a wet chemical etch operation, and/or another type of etch operation.

As shown in FIG. 3E, the recesses 310 may have a similar tapered cross-sectional profile as the source/drain interconnect structures 134 and the gate interconnect structures 136 of the layer 130a. In particular, top widths of the recesses 310 may be greater than bottom widths of the recesses 310 such that the widths of the recesses 310 decrease from tops of the recesses 310 to the bottom of the recesses 310.

Conversely, the metallization structures 144 have an inverted cross-sectional profile relative to the recesses 310, the source/drain interconnect structures 134, and the gate interconnect structures 136. In particular, bottom widths of the metallization structures 144 (indicated in FIG. 3E as a dimension D2) may be greater than top widths of the metallization structures 144 (indicated in FIG. 3E as dimension D3) such that the widths of the metallization structures 144 increase from tops of the metallization structures 144 to the bottom of the metallization structures 144. In some implementations, the bottom width (dimension D2) of a metallization structure 144 is included in a range of approximately 8 nanometers to approximately 12 nanometers. However, other values and ranges are within the scope of the present disclosure. In some implementations, the top width (dimension D3) of a metallization structure 144 is included in a range of approximately 6 nanometers to approximately 10 nanometers. However, other values and ranges are within the scope of the present disclosure. In some implementations, a ratio of a bottom width to a top width (D2:D3) of a metallization structure 144 is included in a range of approximately 4:3 to approximately 6:5. However, other values and ranges are within the scope of the present disclosure.

As shown in FIG. 3F, sidewalls of the metallization structures 144 that are exposed through the recesses 310 are oxidized to form the metal-oxide liners 152 from the sidewalls of the metallization structures 144. In other words, the oxidization of the sidewalls of the metallization structures 144 transforms the sidewalls of the metallization structures 144 from a metal material to a metal-oxide material. To oxidize the sidewalls of the metallization structures 144, a semiconductor processing tool (e.g., an annealing tool, an etching tool, an oxidation tool, a deposition tool, a plasma tool) may be used to perform an oxidation operation in which the sidewalls of the metallization structures 144 exposed to oxygen (O) through the recesses 310. In some implementations, the barrier layer 138 resists oxidation during the oxidation operation.

In some implementations, the oxidation operation includes an annealing operation in which the semiconductor device 100 is exposed to a high ambient temperature in a processing chamber of a semiconductor processing tool while an oxygen-based gas is provided into the recesses 310 to oxidize the sidewalls of the 144 to form the metal-oxide liners 152. The oxygen-based gas may include a carbon monoxide (CO) gas, a carbon dioxide (CO₂) gas, an oxygen (O₂) gas, and/or an ozone (O₃) gas, among other examples. In some implementations, the semiconductor device 100 is exposed to an ambient temperature in the processing chamber that is included in a range of approximately 400 degrees Celsius to approximately 800 degrees Celsius to promote oxidation of the sidewalls of the metallization structures 144 using the oxygen-based gas. However, other values and ranges are within the scope of the present disclosure.

In some implementations, the oxidation operation includes a plasma treatment operation in which the semiconductor device 100 is exposed to a plasma in a processing chamber of a semiconductor processing tool while an oxygen-based gas is provided into the recesses 310 to oxidize the sidewalls of the metallization structures 144 to form the metal-oxide liners 152. The oxygen-based gas may include a carbon monoxide (CO) gas, a carbon dioxide (CO₂) gas, an oxygen (O₂) gas, and/or an ozone (O₃) gas, among other examples. In some implementations, the plasma may include an oxygen plasma, a carbon dioxide plasma, and/or another oxygen-containing plasma. In some implementations, the plasma may include another type of plasma.

The oxidation operation may result in the metal-oxide liners 152 being formed to a thickness (indicated in FIG. 3F as a dimension D4) that is greater than 0 nanometers and up to approximately 1 nanometer. If the metal-oxide liners 152 are formed to a thickness in this range, the metal-oxide liners 152 may provide sufficient structural support for the metallization structures 144 to reduce and/or minimize the likelihood of collapse of the metallization structures 144 while achieving a relatively low electrical resistance for the metallization structures 144. However, other values and ranges are within the scope of the present disclosure.

Since the sidewalls of the metallization structures 144 are oxidized to form the metal-oxide liners 152, the recesses 310 experience minimal to no decrease in lateral width. This enables a greater amount of electrical insulation to be achieved between metallization structures 144 and a lesser amount of parasitic capacitance to be achieved between metallization structures 144 than if liners were deposited in the recesses (e.g., by CVD or ALD).

As shown in FIG. 3G, the recesses 310 may be filled with a sacrificial layer 312. The sacrificial layer 312 may include a polymer material and/or another type of material that enables the sacrificial layer 312 to be subsequently removed with minimal to no removal of materials surrounding the sacrificial layer 312. For example, the sacrificial layer 312 may include a silicon-based polymer material, such as an organosilane (e.g., a silicon-based hydrocarbon (CxHy)). However, other polymer materials are within the scope of the present disclosure.

In some implementations, a deposition tool is used to deposit the material of the sacrificial layer 312 using a CVD technique, a PVD technique, an ALD technique, and/or another suitable deposition technique. In some implementations, a deposition tool is used to dispense the material of the sacrificial layer 312 into the recesses 310 such that the sacrificial layer 312 is in contact with the metal-oxide liners 152 in the recesses 310. In some implementations, a deposition tool is used to dispense the material of the sacrificial layer 312 into the recesses 310 and a curing agent to cure the material of the sacrificial layer 312. The sacrificial layer 312 may be formed such that the sacrificial layer 312 fully fills the recesses 310 and extends above (and merges above) the recesses 310.

As shown in FIG. 3H, a portion of the sacrificial layer 312 (e.g., the sacrificial polymer layer) may be removed to form sacrificial plugs 314 in the recesses 310. The sacrificial plugs 314 (e.g., sacrificial polymer plugs) partially fill the recesses 310, leaving room at the top of the recesses 310 for additional material to be deposited in the recesses 310.

In some implementations, an etch tool may be used to perform an etch operation (e.g., etch back operation) to remove the portion of the sacrificial layer 312 to form the sacrificial plugs 314. In some implementations, the etch operation includes a wet etch operation, a dry etch operation, a plasma-based etch operation, and/or another suitable etch operation.

As shown in FIG. 3I, a supporting layer 150 may be formed in the recesses 310. The supporting layer 150 may include a conformal layer that conforms to the profile of the remaining area in the recesses 310. The supporting layer 150 may be formed on the top surfaces of the sacrificial plugs 314 in the recesses 310, and on the sidewalls of the recesses 310 (which correspond to exposed portions of the metal-oxide liners 152). Thus, the supporting layer 150 may be in contact with the top surfaces of the sacrificial plugs 314 in the recesses 310, and in contact with the exposed portions of the metal-oxide liners 152 in the recesses 310.

Without the sacrificial plugs 314, the supporting layer 150 would otherwise be formed on the bottom of the recesses 310. The sacrificial plugs 314 enable the supporting layer 150 to be formed higher up in the recesses 310 so that the sacrificial plugs 314 can be subsequently removed to form the air spacers 146.

In some implementations, a deposition tool may be used to deposit the supporting layer 150 using a conformal deposition technique such as ALD. In some implementations, a deposition tool may be used to deposit the supporting layer 150 using another deposition technique such as CVD and/or PVD, among other examples.

The supporting layer 150 may include a dielectric material. For example, the supporting layer 150 may include an oxide material such as a silicon oxide-based material. Examples of such materials include silicon dioxide (SiO₂), silicon oxycarbide (SiOC), silicon oxynitride (SiON), and/or silicon oxycarbonitride (SiOCN), among other examples.

As further shown in FIG. 3I, a sacrificial plug 314 may have a dimension D5 that corresponds to the height or vertical (z-direction) thickness of the sacrificial plug 314. The height or vertical (z-direction) thickness of the sacrificial plug 314 may be less than the height of the recess 310 to the top of the metal layer 140 to provide room for dielectric plugs that are to be formed in the remaining area in the recess 310. The greater the height or vertical (z-direction) thickness of the sacrificial plug 314 (dimension D5), the more room that is provided for the air spacers 146 of the isolation structures 142, which enables a lower dielectric constant to be achieved for the isolation structures 142 for reduced parasitic capacitance.

However, the greater the height or vertical (z-direction) thickness of the sacrificial plug 314 (dimension D5), the higher up in the recess 310 the supporting layer 150 is located (indicated in FIG. 3I as dimension D6). The higher up in the recess 310 the supporting layer 150 is located, the wider the gap that the supporting layer 150 has to span across in the recess 310 because of the taper of the recess 310 results in the width of the recess 310 being greater at the top of the recess 310 than at the bottom of the recess 310. The wider the gap that the supporting layer 150 has to span across in the recess 310 the higher the likelihood that the supporting layer 150 may collapse under the weight of the dielectric plug that is to be formed on the supporting layer 150 in the recess 310.

In some implementations, a ratio of the height or vertical (z-direction) thickness of the sacrificial plug 314 to the remaining vertical (z-direction) area in the recess 310 may be included in a range of approximately 2:1 to approximately 10:1 to provide sufficient area for the air spacers 146 (e.g., so that a low dielectric constant can be achieved) while a sufficiently low likelihood of collapse of the supporting layer 150 may be achieved. However, other values and ranges are within the scope of the present disclosure.

As shown in FIG. 3J, the sacrificial plugs 314 may be removed from the recesses 310 after the supporting layer 150 is formed. Removal of the sacrificial plugs 314 results in formation of the air spacers 146 of the isolation regions 142 between the bottoms of the recesses 310 and the sacrificial layer 314.

To remove the sacrificial plugs 314, a high-temperature operation (referred to as a burn out operation) may be performed to dislodge the material of the sacrificial plugs 314. For example, the sacrificial plugs 314 may be heated to a temperature of approximately 400 degrees Celsius or greater to cause or induce thermal cracking in the sacrificial plugs 314. This breaks up the sacrificial plugs 314 and enables the material of the sacrificial plugs 314 to be removed from the recesses 310 through the supporting layer 150.

The material of the supporting layer 150 may have a greater density than the material of the sacrificial plugs 314. This enables the sacrificial plugs 314 to withstand the high-temperature operation. In some implementations, pores may form in the supporting layer 150, and the pores enable the sacrificial plugs 314 to be removed from the supporting layer 150. In particular, material of the sacrificial plugs 314 may be removed through the pores in the supporting layer 150.

As shown in FIG. 3K, a dielectric plug layer 318 is formed in the top portions of the recesses 310 on the supporting layer 150. This results in the recesses 310 being sealed at the top, which results in formation of the air spacers 146 of the isolation regions 142 between the metallization structures 144. The supporting layer 150 prevents, minimizes, and/or otherwise reduces material of the dielectric plug layer 318 that is deposited further down in (e.g., at the bottom of) the recesses 310.

A deposition tool may be used to deposit the dielectric plug layer 318 using a PVD technique, an ALD technique, a CVD technique, an oxidation technique, and/or another suitable deposition technique. The dielectric plug layer 318 may be deposited in one or more deposition operations.

Since the sidewalls of the metallization structures 144 are oxidized to form the metal-oxide liners 152, the recesses 310 experience minimal to no decrease in lateral width. This provides for a larger area within the recesses 310 in which the material of the dielectric plug layer 318 can be deposited, thereby enabling greater gap-filling performance (and thus, a lesser likelihood of void formation in the dielectric plug layer 318) to be achieved than if liners were deposited in the recesses 310 (e.g., by CVD or ALD).

As shown in FIG. 3L, a planarization tool may be used to perform a planarization operation (e.g., a CMP operation) to planarize the dielectric plug layer 318 to remove excess material from the dielectric plug layer 318. The patterning layers 304-308 of the patterning stack 302 may also be removed in the planarization operation. Removal of the excess material of the dielectric plug layer 318 results in formation of the dielectric plugs 148 above the air spacers 146 of the isolation regions 142.

In some implementations, the remaining vertical (z-direction) area (indicated in FIG. 3L as a dimension D5) in an air spacer 146 may be included in a range of approximately 10 nanometers to approximately 20 nanometers. However, other values and ranges are within the scope of the present disclosure. In some implementations, the vertical (z-direction) thickness (indicated in FIG. 3L as a dimension D6) of a dielectric plug 148 may be included in a range of approximately 5 nanometers to approximately 20 nanometers. However, other values and ranges are within the scope of the present disclosure. In some implementations, a ratio of the remaining vertical (z-direction) area in an air spacer 146 to a vertical (z-direction) thickness of a dielectric plug 148 may be included in a range of approximately 2:1 to approximately 10:1. However, other values and ranges are within the scope of the present disclosure.

As shown in FIG. 3M, additional layers 130b-130e and 132b-132e of the interconnect layer 104 may be formed above the layer 132a. The layers 130b-130e and 132b-132e may be formed using copper interconnect formation techniques. For example, one or more deposition tools may be used to deposit alternating layers of ILD layers 126 and ESLs 128 in the interconnect layer 104 for the layers 130b-130e and 132b-132e. As another example, a deposition tool, an exposure tool, a developer tool, an etch tool, a planarization tool, a plating tool, and/or another semiconductor processing tool may be used to perform various operations to form the interconnect structures 154 of the layers 130b-130e, and/or to form the metallization structures 156 of the layers 132b-132e.

The ILD layers 126 and ESLs 128 may be arranged in the z-direction in the semiconductor device 100. One or more deposition tools may be used to deposit each of the ILD layers 126 and each of the ESLs 128 using a PVD technique, an ALD technique, a CVD technique, an oxidation technique, and/or another suitable deposition technique. In some implementations, a planarization tool may be used to planarize the ILD layers 126 and/or the ESLs 128 after the ILD layers 126 and/or the ESLs 128 are deposited.

In some implementations, the interconnect layer 104 may be formed in a plurality of layers. For example, an ILD layer 126 and an ESL 128 of the layer 130b (e.g., the V1 layer) and/or of the layer 132b (e.g., the M1 layer) may be formed (e.g., using one or more deposition tools and/or one or more planarization tools), recesses may be formed in and/or through the ILD layer 126 and the ESL 128 (e.g., using an exposure tool, a developer tool, and/or an etch tool), and the interconnect structures 154 of the layer 130b and/or the metallization structures 156 of the layer 132b may be formed in the ILD layer 126 and the ESL 128 (e.g., using one or more deposition tools and/or one or more planarization tools). This process may be referred to as a dual damascene process. Alternatively, single damascene processes may be performed to form the interconnect structures 154 of the layer 130b and the metallization structures 156 of the layer 132b.

Another ILD layer 126 and another ESL 128 of the layer 130c (e.g., the V2 layer) and/or of the layer 132c (e.g., the M2 layer) may be formed (e.g., using one or more deposition tools and/or one or more planarization tools), recesses may be formed in and/or through the ILD layer 126 and the ESL 128 (e.g., using an exposure tool, a developer tool, and/or an etch tool), and the interconnect structures 154 of the layer 130c and/or the metallization structures 156 of the layer 132c may be formed in the ILD layer 126 and the ESL 128 (e.g., using one or more deposition tools and/or one or more planarization tools).

One or more deposition tools may be used to deposit the interconnect structures 154 and/or the metallization structures 156 using a PVD technique, an ALD technique, a CVD technique, an electroplating technique (e.g., an electro-chemical plating technique), and/or another suitable deposition technique. In some implementations, a planarization tool may be used to planarize the interconnect structures 154 and/or the metallization structures 156 after the interconnect structures 154 and/or the metallization structures 156 are deposited.

Additional layers of the interconnect layer 104 may be formed in a similar manner.

As indicated above, FIGS. 3A-3M is provided as an example. Other examples may differ from what is described with regard to FIGS. 3A-3M.

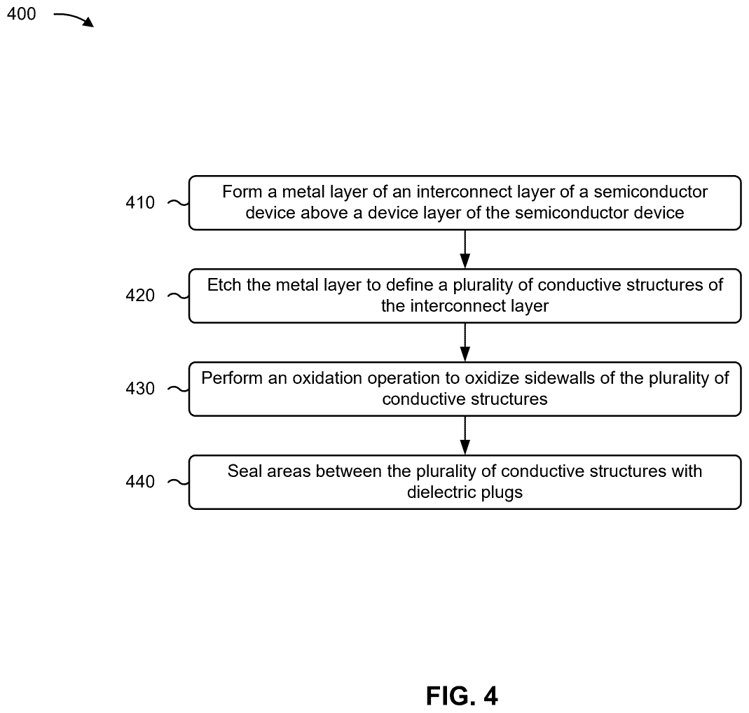

FIG. 4 is a flowchart of an example process 400 associated with forming a semiconductor device described herein. In some implementations, one or more process blocks of FIG. 4 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 4, process 400 may include forming a metal layer (140) of an interconnect layer of a semiconductor device above a device layer of the semiconductor device (block 410). For example, one or more semiconductor processing tools may be used to form a metal layer (e.g., a metal layer 140) of an interconnect layer (e.g., an interconnect layer 104) of a semiconductor device (e.g., a semiconductor device 100) above a device layer (e.g., a device layer 102) of the semiconductor device, as described herein.

As further shown in FIG. 4, process 400 may include etching the metal layer to define a plurality of conductive structures of the interconnect layer (block 420). For example, one or more semiconductor processing tools may be used to etch the metal layer to define a plurality of conductive structures (e.g., metallization structures 144) of the interconnect layer, as described herein. In some implementations, at least one conductive structure of the plurality of conductive structures is electrically coupled to an interconnect structure (e.g., a source/drain interconnect structure 134, a gate interconnect structure 136) above the device layer.

As further shown in FIG. 4, process 400 may include performing an oxidation operation to oxidize sidewalls of the plurality of conductive structures (block 430). For example, one or more semiconductor processing tools may be used to perform an oxidation operation to oxidize sidewalls of the plurality of conductive structures, as described herein.

As further shown in FIG. 4, process 400 may include sealing areas between the plurality of conductive structures with dielectric plugs (block 440). For example, one or more semiconductor processing tools may be used to seal areas between the plurality of conductive structures with dielectric plugs (e.g., dielectric plugs 148), as described herein.

Process 400 may include additional implementations, such as any single implementation or any combination of implementations described below and/or in connection with one or more other processes described elsewhere herein.

In a first implementation, performing the oxidation operation comprises performing an annealing operation using an oxygen-containing gas to oxidize the sidewalls of the plurality of conductive structures.

In a second implementation, alone or in combination with the first implementation, performing the oxidation operation comprises performing a plasma-based operation using an oxygen-containing gas to oxidize the sidewalls of the plurality of conductive structures.

In a third implementation, alone or in combination with one or more of the first and second implementations, process 400 includes forming a bottom barrier layer (e.g., a barrier layer 138) above the device layer, and forming the metal layer includes forming the metal layer on the bottom barrier layer, where the bottom barrier layer resists oxidation during the oxidation operation.

In a fourth implementation, alone or in combination with one or more of the first through third implementations, the metal layer includes ruthenium (Ru), and oxygen (O) from the oxidation operation reacts with the sidewalls of the plurality of conductive structures to transform the sidewalls from ruthenium to ruthenium oxide (RuOₓ).

In a fifth implementation, alone or in combination with one or more of the first through fourth implementations, sealing the areas between the plurality of conductive structures includes forming a supporting layer (e.g., a supporting layer 150 in the areas between the plurality of conductive structures, and forming the dielectric plugs on the supporting layer in the areas between the plurality of conductive structures, where the supporting layer is formed on portions of the sidewalls of the plurality of conductive structures after the oxidation operation.

In a sixth implementation, alone or in combination with one or more of the first through fifth implementations, sealing the areas between the plurality of conductive structures includes forming the dielectric plugs on the supporting layer.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

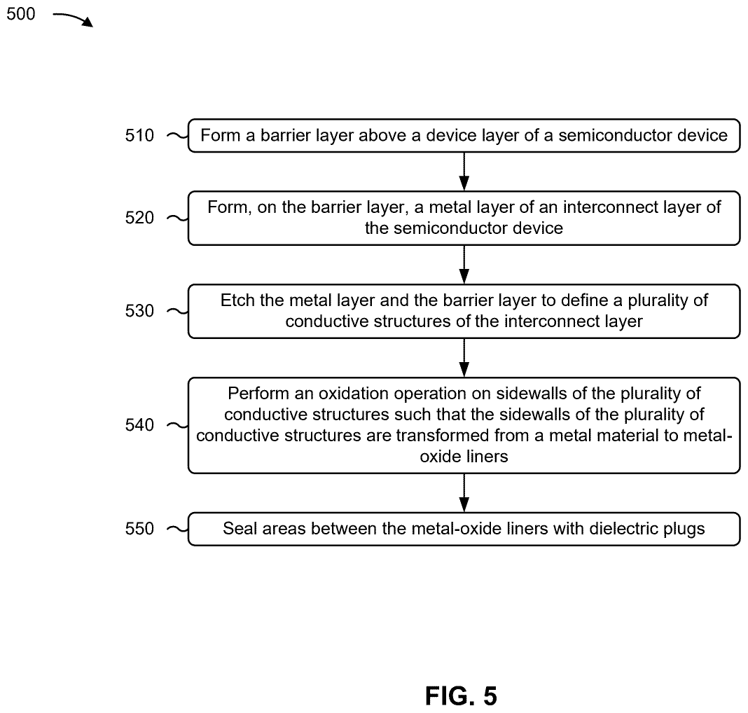

FIG. 5 is a flowchart of an example process 500 associated with forming a semiconductor device. In some implementations, one or more process blocks of FIG. 5 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 5, process 500 may include forming a barrier layer above a device layer of a semiconductor device (block 510). For example, one or more semiconductor processing tools may be used to form a barrier layer (e.g., a barrier layer 138) above a device layer (e.g., a device layer 102) of a semiconductor device (e.g., a semiconductor device 100), as described herein.

As further shown in FIG. 5, process 500 may include forming, on the barrier layer, a metal layer of an interconnect layer (104) of the semiconductor device (block 520). For example, one or more semiconductor processing tools may be used to form, on the barrier layer, a metal layer (e.g., a metal layer 140) of an interconnect layer (e.g., an interconnect layer 104) of the semiconductor device, as described herein.

As further shown in FIG. 5, process 500 may include etching the metal layer and the barrier layer to define a plurality of conductive structures of the interconnect layer (block 530). For example, one or more semiconductor processing tools may be used to etch the metal layer and the barrier layer to define a plurality of conductive structures (e.g., metallization structures 144) of the interconnect layer, as described herein. In some implementations, a conductive structure (e.g., a metallization structure 144) of the plurality of conductive structures is electrically coupled to an interconnect structure (e.g., a source/drain interconnect structure 134, a gate interconnect structure 136) above the device layer.

As further shown in FIG. 5, process 500 may include performing an oxidation operation on sidewalls of the plurality of conductive structures such that the sidewalls of the plurality of conductive structures are transformed from a metal material to metal-oxide liners (block 540). For example, one or more semiconductor processing tools may be used to perform an oxidation operation on sidewalls of the plurality of conductive structures such that the sidewalls of the plurality of conductive structures are transformed from a metal material to metal-oxide liners (e.g., metal-oxide liners 152), as described herein.

As further shown in FIG. 5, process 500 may include sealing areas between the metal-oxide liners with dielectric plugs (block 550). For example, one or more semiconductor processing tools may be used to seal areas between the metal-oxide liners with dielectric plugs (e.g., dielectric plugs 148), as described herein.

Process 500 may include additional implementations, such as any single implementation or any combination of implementations described below and/or in connection with one or more other processes described elsewhere herein.

In a first implementation, performing the oxidation operation includes performing an annealing operation using at least one of a carbon monoxide (CO) gas, a carbon dioxide (CO₂) gas, or an oxygen (O₂) gas.

In a second implementation, alone or in combination with the first implementation, performing the oxidation operation includes performing a plasma-based operation using at least one of a carbon monoxide (CO) gas, a carbon dioxide (CO₂) gas, or an oxygen (O₂) gas.

In a third implementation, alone or in combination with one or more of the first and second implementations, sealing the areas between the metal-oxide liners with the dielectric plugs includes partially filling the areas between the metal-oxide liners with sacrificial polymer plugs, forming a supporting layer on the metal-oxide liners and on tops of the sacrificial polymer plugs in unfilled areas between the metal-oxide liners, wherein the supporting layer is in contact with the metal-oxide liners, and forming the dielectric plugs on the supporting layer in the unfilled areas between the metal-oxide liners.

In a fourth implementation, alone or in combination with one or more of the first through third implementations, the sacrificial polymer plugs are in contact with the metal-oxide liners.

In a fifth implementation, alone or in combination with one or more of the first through fourth implementations, partially filling the areas between the metal-oxide liners with the sacrificial polymer plugs includes forming a polymer layer in the areas between the metal-oxide liners, wherein the polymer layer is in contact with the metal-oxide liners, and etching the polymer layer to form the sacrificial polymer plugs.

In a sixth implementation, alone or in combination with one or more of the first through fifth implementations, process 500 includes performing a burn out operation to remove the sacrificial polymer plugs after forming the dielectric plugs, where the supporting layer remains in contact with the metal-oxide liners after the sacrificial polymer plugs are removed, and where the burn out operation is a thermal operation that is performed to induce thermal cracking in the sacrificial polymer plugs so that material the sacrificial polymer plugs is removed through the supporting layer.

In a seventh implementation, alone or in combination with one or more of the first through sixth implementations, the barrier layer resists oxidation during the oxidation operation.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

In this way, a layer of conductive material is formed above a bottom-most layer of interconnect structures in an interconnect layer of a semiconductor device, and the layer of conductive material is etched to define the bottom-most layer of metallization structures from the layer of conductive material, as opposed to forming the bottom-most layer of metallization structures in recesses in a dielectric layer. To reduce the likelihood of collapse of the free-standing metallization structures, the exposed sidewall surfaces of the free-standing metallization structures may be oxidized to form metal-oxide sidewalls for the free-standing metallization structures. The metal-oxide sidewalls may be formed using a self-aligned oxidation technique that specifically targets the sidewalls of the free-standing metallization structures for oxidation. The metal-oxide sidewalls may be formed of a metal-oxide material that increases the mechanical strength of the free-standing metallization structures (which enables the free-standing metallization structures to resist collapsing) and that has a low electrical resistance (which has minimal impact on the resistance of the free-standing metallization structures). In this way, the low electrical resistance achieved for the bottom-most layer of metallization structures, alone or in combination with the low-k electrical isolation provided by the airgaps, enables a low resistance-capacitance (RC) time constant to be achieved for the bottom-most layer of metallization structures. The low RC time constant enables faster signal propagation speeds to be achieved through the bottom-most layer of metallization structures and/or enables faster switching speeds to be achieved for the integrated circuit devices of the semiconductor device, among other examples.

As described in greater detail above, some implementations described herein provide a method. The method includes forming a metal layer of an interconnect layer of a semiconductor device above a device layer of the semiconductor device. The method includes etching the metal layer to define a plurality of conductive structures of the interconnect layer, where at least one conductive structure of the plurality of conductive structures is electrically coupled to an interconnect structure above the device layer. The method includes performing an oxidation operation to oxidize sidewalls of the plurality of conductive structures. The method includes sealing areas between the plurality of conductive structures with dielectric plugs.

As described in greater detail above, some implementations described herein provide a method. The method includes forming a barrier layer above a device layer of a semiconductor device. The method includes forming, on the barrier layer, a metal layer of an interconnect layer of the semiconductor device. The method includes etching the metal layer and the barrier layer to define a plurality of conductive structures of the interconnect layer, where a conductive structure of the plurality of conductive structures is electrically coupled to an interconnect structure above the device layer. The method includes performing an oxidation operation on sidewalls of the plurality of conductive structures such that the sidewalls of the plurality of conductive structures are transformed from a metal material to metal-oxide liners. The method includes sealing areas between the metal-oxide liners with dielectric plugs.

As described in greater detail above, some implementations described herein provide a semiconductor device. The semiconductor device includes a substrate layer. The semiconductor device includes an integrated circuit device at least one of in or on the substrate layer. The semiconductor device includes an interconnect structure in a dielectric layer above the substrate layer and electrically coupled to the integrated circuit device. The semiconductor device includes a conductive structure above the dielectric layer and electrically coupled to the interconnect structure, where a main body of the conductive structure comprises a metal material, and where sidewalls of the conductive structure comprise a metal-oxide material. The semiconductor device includes an isolation region along at least one sidewall of the conductive structure. The isolation region includes air spacer along a first portion of the sidewall, and a dielectric plug along a second portion of the sidewall above the first portion.

The terms “approximately” and “substantially” can indicate a value of a given quantity that varies within 5% of the value (e.g., +1%, +2%, +3%, +4%, +5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a metal layer of an interconnect layer of a semiconductor device above a device layer of the semiconductor device;
etching the metal layer to define a plurality of conductive structures of the interconnect layer,
wherein at least one conductive structure of the plurality of conductive structures is electrically coupled to an interconnect structure above the device layer;
performing an oxidation operation to oxidize sidewalls of the plurality of conductive structures; and
sealing areas between the plurality of conductive structures with dielectric plugs.

2. The method of claim 1, wherein performing the oxidation operation comprises:
performing an annealing operation using an oxygen-containing gas to oxidize the sidewalls of the plurality of conductive structures.

3. The method of claim 1, wherein performing the oxidation operation comprises:
performing a plasma-based operation using an oxygen-containing gas to oxidize the sidewalls of the plurality of conductive structures.

4. The method of claim 1, further comprising:
forming a bottom barrier layer above the device layer,
wherein forming the metal layer comprises:
forming the metal layer on the bottom barrier layer, and
wherein the bottom barrier layer resists oxidation during the oxidation operation.

5. The method of claim 1, wherein the metal layer comprises ruthenium (Ru); and
wherein oxygen (O) from the oxidation operation reacts with the sidewalls of the plurality of conductive structures to transform the sidewalls from ruthenium to ruthenium oxide (RuOₓ).

6. The method of claim 1, wherein sealing the areas between the plurality of conductive structures comprises:
forming a supporting layer in the areas between the plurality of conductive structures; and
forming the dielectric plugs on the supporting layer in the areas between the plurality of conductive structures,
wherein the supporting layer is formed on portions of the sidewalls of the plurality of conductive structures after the oxidation operation.

7. The method of claim 6, wherein sealing the areas between the plurality of conductive structures comprises:
forming the dielectric plugs on the supporting layer.

8. A method, comprising:
forming a barrier layer above a device layer of a semiconductor device;
forming, on the barrier layer, a metal layer of an interconnect layer of the semiconductor device;
etching the metal layer and the barrier layer to define a plurality of conductive structures of the interconnect layer,
wherein a conductive structure of the plurality of conductive structures is electrically coupled to an interconnect structure above the device layer;
performing an oxidation operation on sidewalls of the plurality of conductive structures such that the sidewalls of the plurality of conductive structures are transformed from a metal material to metal-oxide liners; and
sealing areas between the metal-oxide liners with dielectric plugs.

9. The method of claim 8, wherein performing the oxidation operation comprises:
performing an annealing operation using at least one of:
a carbon monoxide (CO) gas,
a carbon dioxide (CO₂) gas, or
an oxygen (O₂) gas.

10. The method of claim 8, wherein performing the oxidation operation comprises:
performing a plasma-based operation using at least one of:
a carbon monoxide (CO) gas,
a carbon dioxide (CO₂) gas, or
an oxygen (O₂) gas.

11. The method of claim 8, wherein sealing the areas between the metal-oxide liners with the dielectric plugs comprises:
partially filling the areas between the metal-oxide liners with sacrificial polymer plugs;
forming a supporting layer on the metal-oxide liners and on tops of the sacrificial polymer plugs in unfilled areas between the metal-oxide liners,
wherein the supporting layer is in contact with the metal-oxide liners; and
forming the dielectric plugs on the supporting layer in the unfilled areas between the metal-oxide liners.

12. The method of claim 11, wherein the sacrificial polymer plugs are in contact with the metal-oxide liners.

13. The method of claim 11, wherein partially filling the areas between the metal-oxide liners with the sacrificial polymer plugs comprises:
forming a polymer layer in the areas between the metal-oxide liners,
wherein the polymer layer is in contact with the metal-oxide liners; and
etching the polymer layer to form the sacrificial polymer plugs.

14. The method of claim 11, further comprising:
performing a burn out operation to remove the sacrificial polymer plugs after forming the dielectric plugs,
wherein the supporting layer remains in contact with the metal-oxide liners after the sacrificial polymer plugs are removed, and
wherein the burn out operation is a thermal operation that is performed to induce thermal cracking in the sacrificial polymer plugs so that material the sacrificial polymer plugs is removed through the supporting layer.

15. The method of claim 8, wherein the barrier layer resists oxidation during the oxidation operation.

16. A semiconductor device, comprising:
a substrate layer;
an integrated circuit device at least one of in or on the substrate layer;
an interconnect structure in a dielectric layer above the substrate layer and electrically coupled to the integrated circuit device;
a conductive structure above the dielectric layer and electrically coupled to the interconnect structure,
wherein a main body of the conductive structure comprises a metal material, and
wherein sidewalls of the conductive structure comprise a metal-oxide material; and
an isolation region along at least one sidewall of the conductive structure,
wherein the isolation region comprises:
air spacer along a first portion of the sidewall; and
a dielectric plug along a second portion of the sidewall above the first portion.

17. The semiconductor device of claim 16, wherein a first lateral width of a top of the conductive structure is less than a second lateral width of a bottom of the conductive structure.

18. The semiconductor device of claim 16, wherein the metal-oxide material is an oxide of the metal material of the main body of the conductive structure.

19. The semiconductor device of claim 16, wherein the metal material has a polycrystalline structure; and
wherein the metal-oxide material has a monocrystalline structure.

20. The semiconductor device of claim 16, wherein the metal material comprises ruthenium (Ru); and
wherein the metal-oxide material comprises ruthenium dioxide (RuO₂).
